(19) United States
(12) Patent Application Publication
(10) Pub. No.: US 2024/0266402 A1
(43) Pub. Date: Aug. 8, 2024

(54) SEMICONDUCTOR DEVICE AND METHOD OF FABRICATING THE SAME

(71) Applicant: SAMSUNG ELECTRONICS CO., LTD., Suwon-si (KR)

(72) Inventors: Taegon KIM, Suwon-si (KR); Jihye YI, Suwon-si (KR); Yonghee PARK, Suwon-si (KR); Sanghoon HAN, Suwon-si (KR)

(73) Assignee: SAMSUNG ELECTRONICS CO., LTD., Suwon-si (KR)

(21) Appl. No.: 18/393,009

(22) Filed: Dec. 21, 2023

(30) Foreign Application Priority Data
Feb. 6, 2023 (KR) 10-2023-0015769

(51) Int. Cl. H01L 29/15; H01L 29/06; H01L 29/423; H01L 29/66; H01L 29/775; H01L 29/786

(52) U.S. Cl. CPC H01L 29/155; H01L 29/0673; H01L 29/42392; H01L 29/66553; H01L 29/775; H01L 29/78696

(57) ABSTRACT

Provided is a semiconductor device, including a substrate, a first active pattern on the substrate, a first channel pattern on the first active pattern, the first channel pattern including a first semiconductor pattern and a second semiconductor pattern on the first semiconductor pattern, a first source/drain pattern connected to the first channel pattern, and a gate electrode on the first channel pattern, wherein each of the first semiconductor pattern and the second semiconductor pattern includes a plurality of semiconductor layers, and at least one superlattice layer between adjacent semiconductor layers among the plurality of semiconductor layers, wherein the at least one superlattice layer included in the first semiconductor pattern has a first length, wherein the at least one superlattice layer included in the second semiconductor pattern has a second length, and wherein the first length is greater than the second length.

### CROSS-REFERENCE TO RELATED APPLICATION

This U.S. nonprovisional application claims priority to Korean Patent Application No. 10-2023-0015769 filed on Feb. 6, 2023 in the Korean Intellectual Property Office, the disclosure of which is hereby incorporated by reference in its entirety.

### BACKGROUND

Embodiments of the present application relate to a semiconductor device and a method of fabricating the same, and more particularly, to a semiconductor device including a field effect transistor and a method of fabricating the same.

A semiconductor device includes an integrated circuit including metal oxide semiconductor field effect transistors (MOSFETs). As sizes and design rules of the semiconductor device are gradually decreased, sizes of the MOSFETs are also increasingly scaled down. The scale down of MOSFETs may deteriorate operating characteristics of the semiconductor device. Accordingly, various studies have been conducted to develop methods of fabricating semiconductor devices having superior performances while overcoming limitations caused by high integration of the semiconductor devices.

### SUMMARY

One or more embodiments provide a semiconductor device with improved electrical properties and enhanced process efficiency.

One or more embodiments provide a method of fabricating a semiconductor device with improved electrical properties and enhanced process efficiency.

According to an aspect of an embodiment, there is provided a semiconductor device, including a substrate, a first active pattern on the substrate, a first channel pattern on the first active pattern, the first channel pattern including a first semiconductor pattern and a second semiconductor pattern on the first semiconductor pattern, a first source/drain pattern connected to the first channel pattern, and a gate electrode on the first channel pattern, wherein each of the first semiconductor pattern and the second semiconductor pattern includes a plurality of semiconductor layers, and at least one superlattice layer between adjacent semiconductor layers among the plurality of semiconductor layers, wherein the at least one superlattice layer included in the first semiconductor pattern has a first length, wherein the at least one superlattice layer included in the second semiconductor pattern has a second length, and wherein the first length is greater than the second length.

According to another aspect of an embodiment, there is provided a semiconductor device, including a substrate including an active pattern, a channel pattern on the active pattern, the channel pattern including a plurality of nano-sheets vertically stacked and spaced apart from each other, a source/drain pattern connected to the channel pattern, and a gate electrode on the channel pattern, wherein each of the plurality of nano-sheets includes semiconductor layers and superlattice layers that are alternately stacked, and wherein a number of the superlattice layers in a first tier of the plurality of nano-sheets is greater than a number of the superlattice layers in a second tier of the plurality of nano-sheets, the first tier being above the second tier.

According to another aspect of an embodiment, there is provided a semiconductor device, including a substrate including an active pattern, a device isolation layer filling a trench, a channel pattern and a source/drain pattern on the active pattern, the channel pattern including a plurality of nano-sheets that are vertically stacked and spaced apart from each other, a gate electrode on the channel pattern, the gate electrode including a plurality of inner electrodes between the plurality of nano-sheets, a gate dielectric layer adjacent to each of the plurality of inner electrodes included in the gate electrode, a gate spacer on a sidewall of the gate electrode, a gate capping pattern on a top surface of the gate electrode, an interlayer dielectric layer on the gate capping pattern, an active contact penetrating the interlayer dielectric layer and electrically connected to the source/drain pattern, a metal-semiconductor compound layer between the active contact and the source/drain pattern, a gate contact penetrating the interlayer dielectric layer and the gate capping pattern and electrically connected to the gate electrode, and a first metal layer on the interlayer dielectric layer, wherein the first metal layer includes a plurality of first wiring lines electrically connected to the active contact and the gate contact, wherein each of the plurality of nano-sheets includes at least one superlattice layer, and wherein a number of the at least one superlattice layer in each of the plurality of nano-sheets increases in a direction from a lowermost nano-sheet among the plurality of nano-sheets toward an uppermost nano-sheet among the plurality of nano-sheets.

### BRIEF DESCRIPTION OF THE DRAWINGS

The above and other aspects, features, and advantages of the embodiments will be more clearly understood from the following detailed description, taken in conjunction with the accompanying drawings, in which:

FIGS. 1, 2, and 3 illustrate conceptual views showing logic cells of a semiconductor device according to embodiments:

FIG. 4 illustrates a plan view showing a semiconductor device according to embodiments:

FIGS. 5A, 5B, 5C, and 5D illustrate cross-sectional views respectively taken along lines A-A′, B-B′, C-C′, and D-D′ of FIG. 4;

FIG. 6 illustrates an enlarged view showing an example of section M depicted in FIG. 5A:

FIGS. 7A, 7B, 8A, 8B, 9A, 9B, 9C, 9D, 10A, 10B, 10C, 10D, 11A, 11B, 11C, 11D, 12A, 12B, 12C, 12D, 13A, 13B, 13C, and 13D illustrate cross-sectional views showing a method of fabricating a semiconductor device according to embodiments; and

FIGS. 14, 15, and 16 illustrate enlarged views showing a semiconductor device according to embodiments.

### DETAILED DESCRIPTION

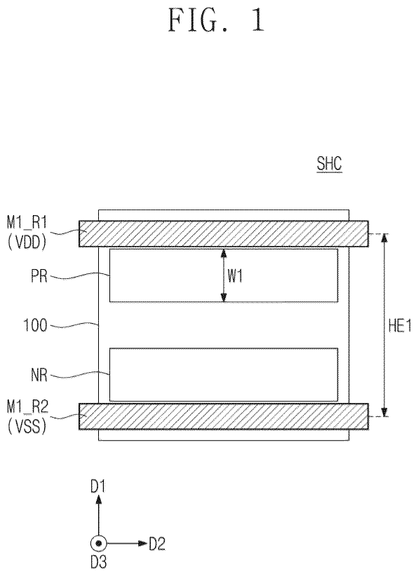

FIGS. 1 to 3 illustrate conceptual views showing logic cells of a semiconductor device according to embodiments.

Referring to FIG. 1, a single height cell SHC may be provided. For example, a substrate 100 may be provided thereon with a first power line M1_R1 and a second power line M1_R2. The first power line M1_R1 may be a path for providing a drain voltage VDD, for example, a power voltage. The second power line M1_R2 may be a path for providing a source voltage VSS, for example, a ground voltage.

The single height cell SHC may be formed between the first power line M1_R1 and the second power line M1_R2. The single height cell SHC may include one PMOSFET region PR and one NMOSFET region NR. For example, the single height cell SHC may have a complementary metal oxide semiconductor (CMOS) structure provided between the first power line M1_R1 and the second power line M1_R2.

Each of the PMOSFET and NMOSFET regions PR and NR may have a first width WI in a first direction D1. A first height HE1 may be a length in the first direction D1 of the single height cell SHC. The first height HE1 may be substantially the same as a distance (e.g., pitch) between the first power line M1_R1 and the second power line M1_R2.

The single height cell SHC may constitute one logic cell. In this description, the logic cell may mean a logic device, such as AND, OR, XOR, XNOR, and inverter, that performs a specific function. For example, the logic cell may include transistors for constituting a logic device, and may also include wiring lines that connect the transistors to each other.

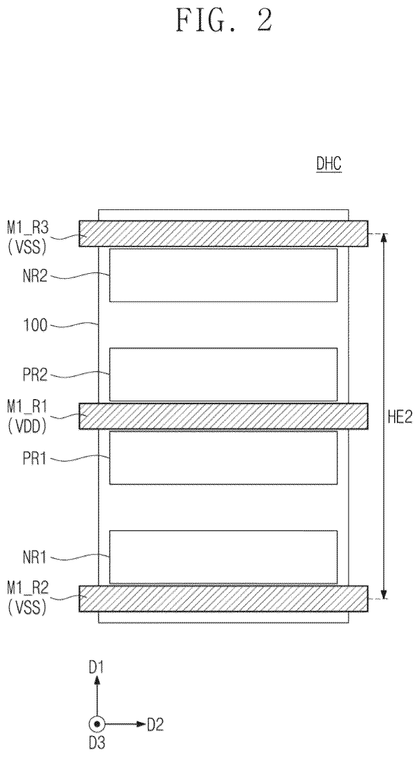

Referring to FIG. 2, a double height cell DHC may be provided. For example, a substrate 100 may be provided thereon with a first power line M1_R1, a second power line M1_R2, and a third power line M1_R3. The first power line M1_R1 may be disposed between the second power line M1_R2 and the third power line M1_R3. The third power line M1_R3 may be a path for providing a drain voltage VDD.

The double height cell DHC may be formed between the second power line M1_R2 and the third power line M1_R3. The double height cell DHC may include a first PMOSFET region PR1, a second PMOSFET region PR2, a first NMOSFET region NR1, and a second NMOSFET region NR2.

The first NMOSFET region NR1 may be adjacent to the second power line M1_R2. The second NMOSFET region NR2 may be adjacent to the third power line M1_R3. The first PMOSFET region PR1 and the second PMOSFET region PR2 may be adjacent to the first power line M1_R1. When viewed in a plan view, the first power line M1_R1 may be located between the first PMOSFET region PR1 and the second PMOSFET region PR2.

A second height HE2 may be a length in the first direction D1 of the double height cell DHC. The second height HE2 may be about twice the first height HE1 of the single height cell SHC in FIG. 1. The first PMOSFET region PR1 and the second PMOSFET region PR2 of the double height cell DHC may collectively operate as a single PMOSFET region.

Therefore, the double height cell DHC may have a PMOS transistor whose channel size is greater than that of a PMOS transistor included in the single height cell SHC in FIG. 1. For example, the channel size of the PMOS transistor included in the double height cell DHC may be about twice of the channel size of the PMOS transistor included in the single height cell SHC. The double height cell DHC may operate at a higher speed than an operation speed of the single height cell SHC. In the embodiments, the double height cell DHC shown in FIG. 2 may be formed as a multi-height cell. The multi-height cell may include a triple height cell whose cell height is about three times the height of the single height cell SHC.

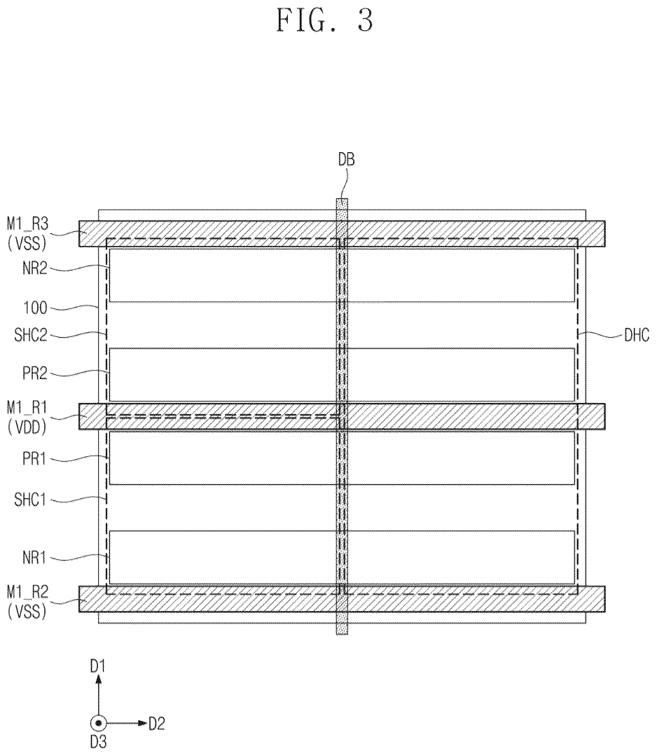

Referring to FIG. 3, a substrate 100 may be provided thereon with a first single height cell SHC1, a second single height cell SHC2, and a double height cell DHC that are two-dimensionally disposed. The first single height cell SHC1 may be disposed between a first power line M1_R1 and a second power line M1_R2. The second single height cell SHC2 may be disposed between the first power line M1_R1 and a third power line M1_R3. The second single height cell SHC2 may be adjacent in a first direction D1 to the first single height cell SHC1.

The double height cell DHC may be disposed between the second power line M1_R2 and the third power line M1_R3. The double height cell DHC may be adjacent in a second direction D2 to the first single height cell SHC1 and the second single height cell SHC2.

A separation structure DB may be provided between the first single height cell SHC1 and the double height cell DHC and between the second single height cell SHC2 and the double height cell DHC. The separation structure DB may electrically separate an active region of the double height cell DHC from an active region of each of the first single height cell SHC1 and the second single height cell SHC2.

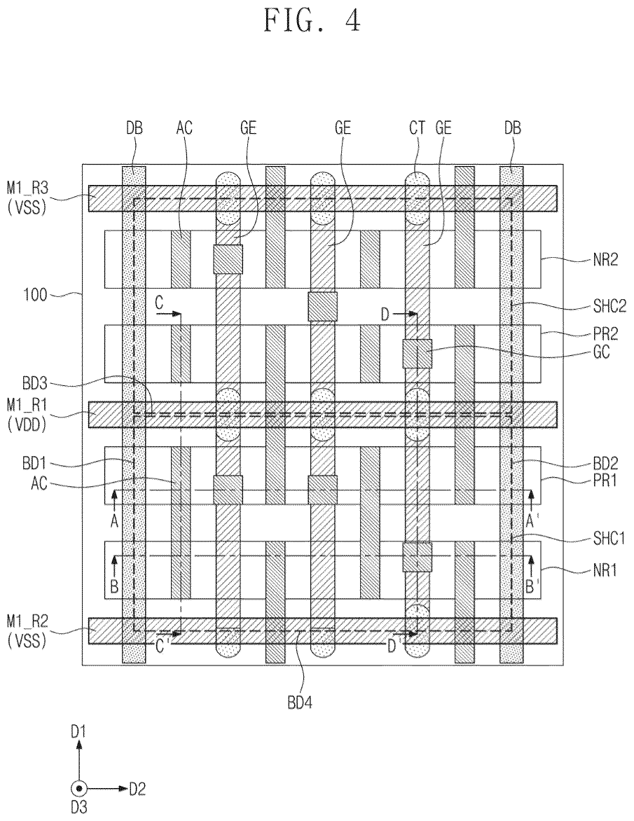

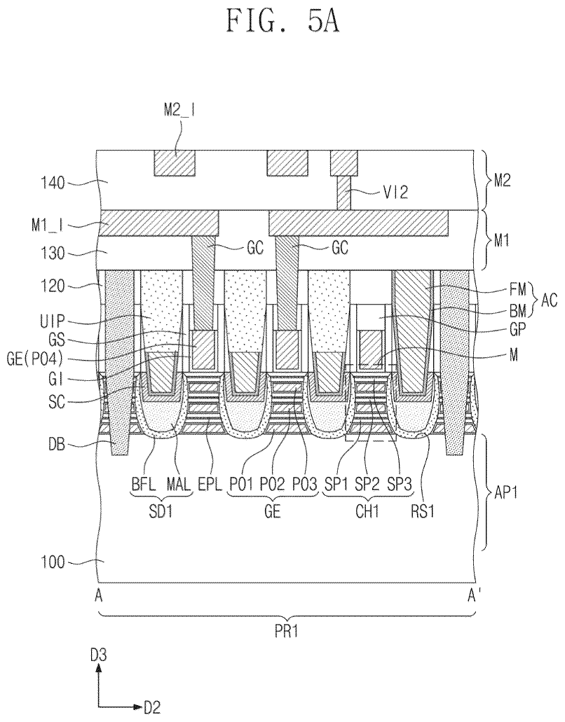

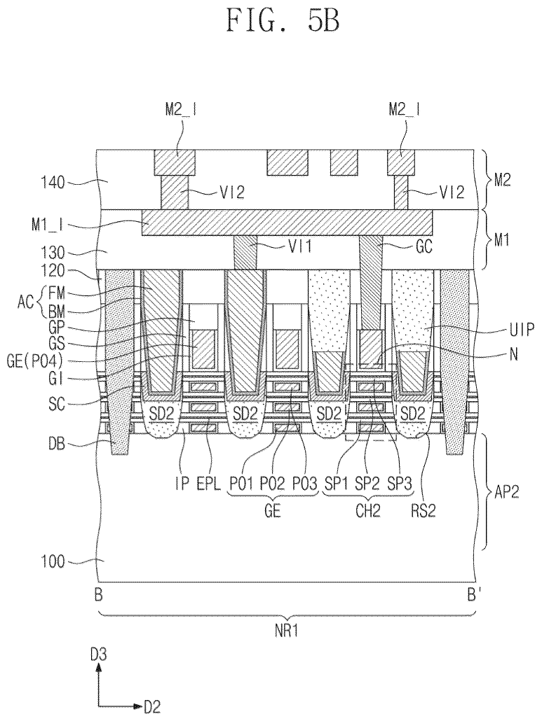

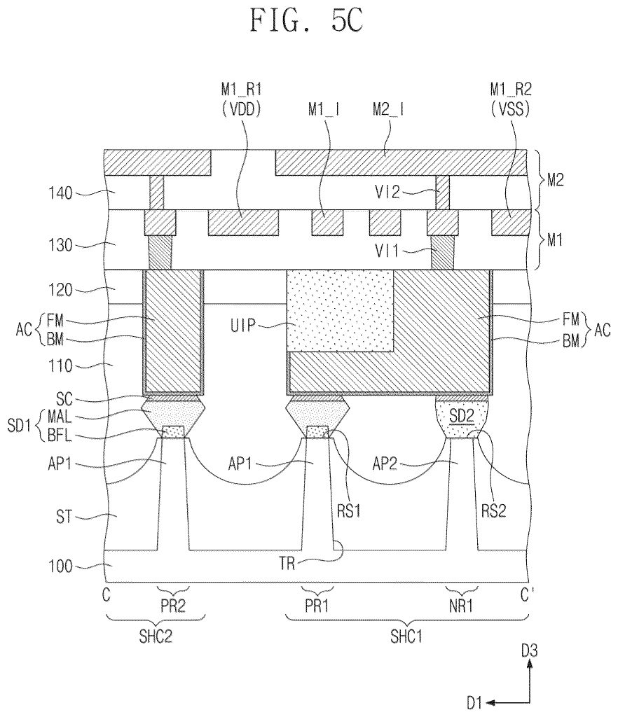

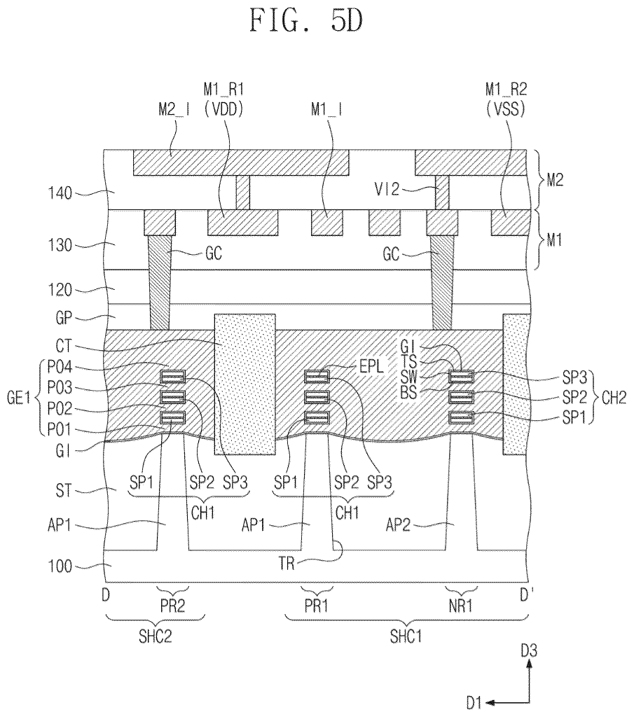

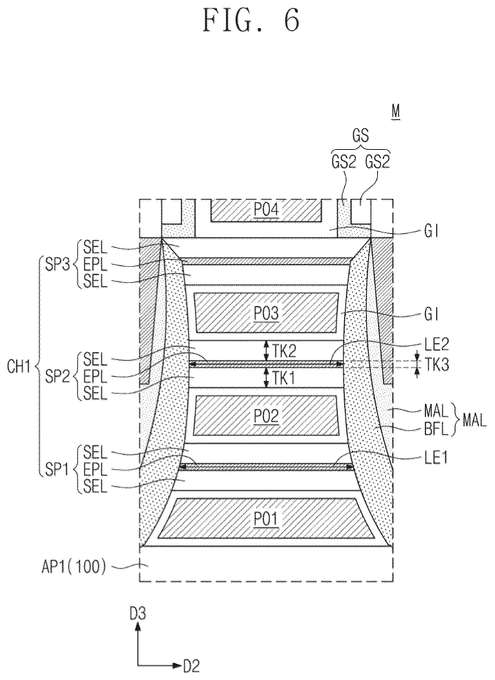

FIG. 4 illustrates a plan view showing a semiconductor device according to embodiments. FIGS. 5A, 5B, 5C, and 5D illustrate cross-sectional views respectively taken along lines A-A′, B-B′, C-C′, and D-D′ of FIG. 4. FIG. 6 illustrates an enlarged view showing an example of section M depicted in FIG. 5A. A semiconductor device shown in FIGS. 4 and 5A to 5D is a detailed example of the first single height cell SHC1 and the second single height cell SHC2 of FIG. 3.

Referring to FIGS. 4 and 5A to 5D, first single height cell SHC1 and the second single height cell SHC2 may be provided on a substrate 100. Each of the first single height cell SHC1 and the second single height cell SHC2 may include logic transistors included in a logic circuit. The substrate 100 may be a compound semiconductor substrate or a semiconductor substrate including silicon, germanium, or silicon-germanium. For example, the substrate 100 may be a silicon substrate.

The substrate 100 may have a first PMOSFET region PR1, a second PMOSFET region PR2, a first NMOSFET region NR1, and a second NMOSFET region NR2. Each of the first PMOSFET region PR1, the second PMOSFET region PR2, the first NMOSFET region NR1, and the second NMOSFET region NR2 may extend in a second direction D2. The first single height cell SHC1 may include the first NMOSFET region NR1 and the first PMOSFET region PR1, and the second single height cell SHC2 may include the second PMOSFET region PR2 and the second NMOSFET region NR2.

A first active pattern AP1 and a second active pattern AP2 may be formed by a trench TR formed on an upper portion of the substrate 100. The first active pattern AP1 may be provided on each of the first PMOSFET region PR1 and the second PMOSFET region PR2. The second active pattern AP2 may be provided on each of the first and second NMOSFET regions NR1 and NR2. The first active pattern AP1 and the second active pattern AP2 may extend in the second direction D2. The first active pattern AP1 and the second active pattern AP2 may be vertically protruding portions of the substrate 100.

The trench TR may be filled with a device isolation layer ST. The device isolation layer ST may include a silicon oxide layer. The device isolation layer ST may not cover any of first channel pattern CH1 and second channel pattern CH2 which will be discussed below.

A first channel pattern CH1 may be provided on the first active pattern AP1. A second channel pattern CH2 may be provided on the second active pattern AP2. Each of the first channel pattern CH1 and second channel pattern CH2 may include a first semiconductor pattern SP1, a second semiconductor pattern SP2, and a third semiconductor pattern SP3 that are sequentially stacked. The first semiconductor pattern SP1, second semiconductor pattern SP2, and third semiconductor pattern SP3 may be spaced apart from each other in a vertical direction (or a third direction D3).

Each of the first semiconductor pattern SP1, second semiconductor pattern SP2, and third semiconductor pattern SP3 may include silicon (Si), germanium (Ge), or silicon-germanium (SiGe). For example, each of the first semiconductor pattern SP1, second semiconductor pattern SP2, and third semiconductor pattern SP3 may include crystalline silicon. The first semiconductor pattern SP1, second semiconductor pattern SP2, and third semiconductor pattern SP3 may vertically overlap each other.

According to some embodiments, each of the first semiconductor pattern SP1, second semiconductor pattern SP2, and third semiconductor pattern SP3 may further include at least one superlattice layer EPL. The superlattice layer EPL may be provided in crystalline silicon. Thus, each of the first semiconductor pattern SP1, second semiconductor pattern SP2, and third semiconductor pattern SP3 may include a superlattice structural nano-sheet. The superlattice layer EPL according to the embodiments will be discussed with reference to FIG. 6.

A plurality of first source/drain patterns SD1 may be provided on the first active pattern AP1. A plurality of first recesses RS1 may be formed on an upper portion of the first active pattern AP1. The first source/drain patterns SD1 may be correspondingly provided in the first recesses RS1. The first source/drain patterns SD1 may be impurity regions having a first conductivity type (e.g., p-type). The first channel pattern CH1 may be interposed between a pair of first source/drain patterns SD1. For example, the pair of first source/drain patterns SD1 may be connected to each other through the stacked first semiconductor pattern SP1, second semiconductor pattern SP2, and third semiconductor pattern SP3.

A plurality of second source/drain patterns SD2 may be provided on the second active pattern AP2. A plurality of second recesses RS2 may be formed on an upper portion of the second active pattern AP2. The second source/drain patterns SD2 may be correspondingly provided in the second recesses RS2. The second source/drain patterns SD2 may be impurity regions having a second conductivity type (e.g., n-type). The second channel pattern CH2 may be interposed between a pair of second source/drain patterns SD2. For example, the pair of second source/drain patterns SD2 may be connected to each other through the stacked first semiconductor pattern SP1, second semiconductor pattern SP2, and third semiconductor pattern SP3.

The first source/drain pattern SD1 and the second source/drain pattern SD2 may be epitaxial patterns formed by a selective epitaxial growth (SEG) process. For example, each of the first source/drain pattern SD1 and the second source/drain pattern SD2 may have a top surface higher than that of the third semiconductor pattern SP3. For another example, at least one of the first source/drain pattern SD1 and the second source/drain pattern SD2 may have a top surface at substantially the same level as a level of a top surface of the third semiconductor pattern SP3 in a vertical direction (D3 direction).

The first source/drain patterns SD1 may include a semiconductor element (e.g., SiGe) whose lattice constant is greater than a lattice constant of a semiconductor element of the substrate 100. Therefore, a pair of first source/drain patterns SD1 may provide the first channel pattern CH1 with compressive stress. The second source/drain patterns SD2 may include the same semiconductor element (e.g., Si) as that of the substrate 100.

Each of the first source/drain patterns SD1 may include a buffer layer BFL and a main layer MAL on the buffer layer BFL. With reference to FIG. 5A, the following will describe a vertical section in the second direction D2 of the first source/drain pattern SD1.

The buffer layer BFL may cover an inner wall of the first recess RS1. In an embodiment, a thickness of the buffer layer BFL may decrease in a direction from lower to upper portions of the buffer layer BFL. For example, a thickness in the second direction D2 of the buffer layer BFL on a bottom surface of the first recess RS1 may be greater than a thickness in the second direction D2 of the buffer layer BFL on an upper portion of the first recess RS1. The buffer layer BFL may have a U shape along a profile of the first recess RS1.

The buffer layer BFL may occupy a portion of the first recess RS1, and the main layer MAL may fill almost unoccupied portion of the first recess RS1. The main layer MAL may have a volume greater than that of the buffer layer BFL. For example, a ratio of volume of the main layer MAL to entire volume of the first source/drain pattern SD1 may be greater than a ratio of volume of the buffer layer BFL to entire volume of the first source/drain pattern SD1.

Each of the buffer layer BFL and the main layer MAL may include silicon-germanium (SiGe). For example, the buffer layer BFL may contain germanium whose concentration is relatively low. In another example, the buffer layer BFL may not include germanium (Ge), but include only silicon (Si). The germanium concentration of the buffer layer BFL may range from about 0 at % to about 10 at %. For example, the germanium concentration of the buffer layer BFL may range from about 2 at % to about 8 at %.

The main layer MAL may contain germanium (Ge) whose concentration is relatively high. For example, the germanium concentration of the main layer MAL may range from about 30 at % to about 70 at %. The germanium concentration of the main layer MAL may increase in the third direction D3. For example, the main layer MAL adjacent to the buffer layer BFL may have a germanium concentration of about 40 at %, and an upper portion of the main layer MAL may have a germanium concentration of about 60 at %.

Each of the buffer layer BFL and the main layer MAL may include impurities (e.g., boron, gallium, or indium) that cause the first source/drain pattern SD1 to have a p-type conductivity. Each of the buffer layer BFL and the main layer MAL may have an impurity concentration of about 1E18 atoms/cm³ to about 5E22 atoms/cm³. The impurity concentration of the main layer MAL may be greater than an impurity concentration of the buffer layer BFL.

The buffer layer BFL may prevent stacking faults between the main layer MAL and the substrate 100 (or the first active pattern AP1) and between the main layer MAL and the first semiconductor pattern SP1, second semiconductor pattern SP2, and third semiconductor pattern SP3. The occurrence of stacking faults may increase a channel resistance. The stacking faults may easily occur at the floor of the first recess RS1. Accordingly, it may be preferable that the buffer layer BFL adjacent to the floor of the first recess RS1 should have a relatively large thickness to prevent the stacking faults.

The buffer layer BFL may protect the main layer MAL while sacrificial layers SAL are replaced with first inner electrode PO1, second inner electrode PO2, and third inner electrode PO3 of a gate electrode GE which will be discussed below. For example, the buffer layer BFL may prevent the main layer MAL from being etched with an etching material that removes the sacrificial layers SAL.

Referring back to FIGS. 4 and 5A to 5D, gate electrodes GE may be formed to extend in a first direction D1 while running across the first channel pattern CH1 and second channel pattern CH2. The gate electrodes GE may be arranged at a first pitch in the second direction D2. Each of the gate electrodes GE may vertically overlap the first channel pattern CH1 and second channel pattern CH2.

The gate electrode GE may include a first inner electrode PO1 interposed between the first semiconductor pattern SP1 and the active pattern AP1 or AP2, a second inner electrode PO2 interposed between the first semiconductor pattern SP1 and the second semiconductor pattern SP2, a third inner electrode PO3 interposed between the second semiconductor pattern SP2 and the third semiconductor pattern SP3, and an outer electrode PO4 on the third semiconductor pattern SP3.

Referring back to FIG. 5A, on the first PMOSFET region PR1, the gate electrode GE may have different widths at the first inner electrode PO1, second inner electrode PO2, and third inner electrode PO3 thereof. For example, a maximum width in the second direction D2 of the third inner electrode PO3 may be greater than a maximum width in the second direction D2 of the second inner electrode PO2. The maximum width in the second direction D2 of the first inner electrode PO1 may be greater than a maximum in the second direction D2 of the third inner electrode PO3.

Referring back to FIG. 5D, the gate electrode GE may be provided on a top surface TS, a bottom surface BS, and opposite sidewalls SW of each of the first semiconductor pattern SP1, second semiconductor pattern SP2, and third semiconductor pattern SP3. For example, a transistor according to the embodiment may be a three-dimensional field effect transistor (e.g., MBCFET or GAAFET) in which the gate electrode GE three-dimensionally surrounds the first channel pattern CH1 and second channel pattern CH2.

Referring back to FIGS. 4 and 5A to 5D, representatively, the first single height cell SHC1 may have a first boundary BD1 and a second boundary BD2 that are opposite to each other in the second direction D2. The first boundary BD1 and the second boundary BD2 may extend in the first direction D1. The first single height cell SHC1 may have a third boundary BD3 and a fourth boundary BD4 that are opposite to each other in the first direction D1. The third boundary BD1 and the fourth boundary BD2 may extend in the second direction D2.

Gate cutting patterns CT may be located on a boundary in the second direction D2 of each of the first single height cell SHC1 and the second single height cell SHC2. For example, the gate cutting patterns CT may be located on the third boundary BD1 and the fourth boundary BD2 of the first single height cell SHC1. The gate cutting patterns CT may be arranged at the first pitch along the third boundary BD3. The gate cutting patterns CT may be arranged at the first pitch along the fourth boundary BD4. When viewed in a plan view, the gate cutting patterns CT on the third boundary BD1 and the fourth boundary BD2 may be located to correspondingly overlap the gate electrodes GE. The gate cutting patterns CT may include a dielectric material, such as a silicon oxide layer, a silicon nitride layer, or a combination thereof.

The gate cutting pattern CT may separate the gate electrode GE on the first single height cell SHC1 from the gate electrode GE on the second single height cell SHC2. The gate cutting pattern CT may be interposed between the gate electrode GE on the first single height cell SHC1 and the gate electrode GE on the second single height cell SHC2, which gate electrodes GE are aligned with each other in the first direction D1. For example, the gate cutting patterns CT may divide the gate electrode GE, which extends in the first direction D1, into a plurality of gate electrodes GE.

A pair of gate spacers GS may be located on opposite sidewalls of each of the gate electrodes GE. The gate spacers GS may extend in the first direction D1 along the gate electrode GE. The gate spacers GS may have their top surfaces higher than a top surface of the gate electrode GE. The top surfaces of the gate spacers GS may be coplanar with a top surface of a first interlayer dielectric layer 110 which will be discussed below. In an embodiment, the gate spacers GS may include at least one selected from silicon carbon nitride (SiCN), silicon carbon oxynitride (SiCON), and silicon nitride (SiN). In another embodiment, the gate spacers GS may include a multiple layer formed of at least two selected from SiCN, SiCON, and SiN.

A gate capping pattern GP may be provided on the gate electrode GE. The gate capping pattern GP may extend in the first direction D1 along the gate electrode GE. The gate capping pattern GP may include a material having an etch selectivity with respect to first and second interlayer dielectric layers 110 and 120 which will be discussed below. For example, the gate capping pattern GP may include at least one selected from SiON, SiCN, SiCON, and SiN.

A gate dielectric layer GI may be interposed between the gate electrode GE and the first channel pattern CH1 and between the gate electrode GE and the second channel pattern CH2. The gate dielectric layer GI may cover the top surface TS, the bottom surface BS, and the opposite sidewalls SW of each of the first semiconductor pattern SP1, second semiconductor pattern SP2, and third semiconductor pattern SP3. The gate dielectric layer GI may cover a top surface of the device isolation layer ST that underlies the gate electrode GE.

In an embodiment, the gate dielectric layer GI may include one or more of a silicon oxide layer, a silicon oxynitride layer, and a high-k dielectric layer. The high-k dielectric layer may include a high-k dielectric material whose dielectric constant is greater than that of a silicon oxide layer. For example, the high-k dielectric material may include one or more of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate.

Alternatively, a semiconductor device according to embodiments may include a negative capacitance field effect transistor that uses a negative capacitor. For example, the gate dielectric layer GI may include a ferroelectric material layer that exhibits ferroelectric properties and a paraelectric material layer that exhibits paraelectric properties.

The ferroelectric material layer may have a negative capacitance, and the paraelectric material layer may have a positive capacitance. For example, when two or more capacitors are connected in series, and when each capacitor has a positive capacitance, an overall capacitance may be reduced to be less than the capacitance of each capacitor. In contrast, when at least one of two or more capacitors connected in series has a negative capacitance, an overall capacitance may have a positive value that is increased to be greater than an absolute value of the capacitance of each capacitor.

When the ferroelectric material layer having a negative capacitance is connected in series to the paraelectric material layer having a positive capacitance, there may be an increase in overall capacitance of the ferroelectric and paraelectric material layers that are connected in series. The increase in overall capacitance may be used to allow a transistor including the ferroelectric material layer to have a sub-threshold swing of less than about 60 mV/decade at room temperature.

The ferroelectric material layer may have ferroelectric properties. The ferroelectric material layer may include, for example, one or more of hafnium oxide, hafnium zirconium oxide, barium strontium titanium oxide, and lead zirconium titanium oxide. For example, the hafnium zirconium oxide may be a material in which hafnium oxide is doped with zirconium (Zr). For another example, the hafnium zirconium oxide may be a compound of hafnium (Hf), zirconium (Zr), and oxygen (O).

The ferroelectric material layer may further include impurities doped therein. For example, the impurities may include at least one selected from aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). The type of impurities included in the ferroelectric material layer may be changed depending on what ferroelectric material is included in the ferroelectric material layer.

When the ferroelectric material layer includes hafnium oxide, the ferroelectric material layer may include at least one of impurities such as gadolinium (Gd), silicon (Si), zirconium (Zr), aluminum (Al), and yttrium (Y).

When the impurities are aluminum (Al), the ferroelectric material layer may include about 3 to 8 atomic percent aluminum. In this description, the ratio of impurities may be a ratio of aluminum to the sum of hafnium and aluminum.

When the impurities are silicon (Si), the ferroelectric material layer may include about 2 to about 10 atomic percent silicon. When the impurities are yttrium (Y), the ferroelectric material layer may include about 2 to about 10 atomic percent yttrium. When the impurities are gadolinium (Gd), the ferroelectric material layer may include about 1 to about 7 atomic percent gadolinium. When the impurities are zirconium (Zr), the ferroelectric material layer may include about 50 to about 80 atomic percent zirconium.

The paraelectric material layer may have paraelectric properties. The paraelectric material layer may include, for example, at least one selected from silicon oxide and high-k metal oxide. The metal oxide included in the paraelectric material layer may include, for example, one or more of hafnium oxide, zirconium oxide, and aluminum oxide, but embodiments are not limited thereto.

The ferroelectric and paraelectric material layers may include the same material. The ferroelectric material layer may have ferroelectric properties, but the paraelectric material layer may not have ferroelectric properties. For example, when the ferroelectric material layer and the paraelectric material layer include hafnium oxide, the hafnium oxide included in the ferroelectric material layer may have a crystal structure different from that of the hafnium oxide included in the paraelectric material layer.

The ferroelectric material layer may have a thickness having ferroelectric properties. The thickness of the ferroelectric material layer may range, for example, from about 0.5 nm to about 10 nm, but embodiments are not limited thereto. Because ferroelectric materials have their own critical thickness that exhibits ferroelectric properties, the thickness of the ferroelectric material layer may depend on ferroelectric material.

For example, the gate dielectric layer GI may include a single ferroelectric material layer. As another example, the gate dielectric layer GI may include a plurality of ferroelectric material layers that are spaced apart from each other. The gate dielectric layer GI may have a stack structure in which a plurality of ferroelectric material layers are alternately stacked with a plurality of paraelectric material layers.

The gate electrode GE may include a first metal pattern and a second metal pattern on the first metal pattern. The first metal pattern may be provided on the gate dielectric layer GI and may be adjacent to the first semiconductor pattern SP1, second semiconductor pattern SP2, and third semiconductor pattern SP3. The first metal pattern may include a work-function metal that controls a threshold voltage of a transistor. A thickness and composition of the first metal pattern may be adjusted to achieve a desired threshold voltage of a transistor. For example, the first inner electrode PO1, second inner electrode PO2, and third inner electrode PO3 of the gate electrode GE may be formed of the first metal pattern or the work-function metal.

The first metal pattern may include a metal nitride layer. For example, the first metal pattern may include nitrogen (N) and at least one metal selected from titanium (Ti), tantalum (Ta), aluminum (Al), tungsten (W), and molybdenum (Mo). In addition, the first metal pattern may further include carbon (C). The first metal pattern may include a plurality of stacked work-function metal layers.

The second metal pattern may include metal whose resistance is less than a resistance of the first metal pattern. For example, the second metal pattern may include at least one metal selected from tungsten (W), aluminum (Al), titanium (Ti), and tantalum (Ta). For example, the outer electrode PO4 of the gate electrode GE may include a first metal pattern and a second metal pattern on the first metal pattern.

Referring back to FIG. 5B, inner spacers IP may be provided on the first NMOSFET region NR1 and the second NMOSFET region NR2. For example, the inner spacers IP may be provided on the second active pattern AP2. The inner spacers IP may be correspondingly interposed between the second source/drain pattern SD2 and the first inner electrode PO1, second inner electrode PO2, and third inner electrode PO3 of the gate electrode GE. The inner spacers IP may be in direct contact with the second source/drain pattern SD2. The inner spacer IP may separate the second source/drain pattern SD2 from each of the first inner electrode PO1, second inner electrode PO2, and third inner electrode PO3 of the gate electrode GE.

A first interlayer dielectric layer 110 may be provided on the substrate 100. The first interlayer dielectric layer 110 may cover the gate spacers GS and the first source/drain pattern SD1 and the second source/drain pattern SD2. The first interlayer dielectric layer 110 may have a top surface substantially coplanar with a top surface of the gate capping pattern GP and that of the gate spacer GS. The first interlayer dielectric layer 110 may be provided thereon with a second interlayer dielectric layer 120 that covers the gate capping pattern GP. A third interlayer dielectric layer 130 may be provided on the second interlayer dielectric layer 120. A fourth interlayer dielectric layer 140 may be provided on the third interlayer dielectric layer 130. For example, the first to fourth interlayer dielectric layers 110 to 140 may include a silicon oxide layer.

Each of the first single height cell SHC1 and the second single height cell SHC2 may be provided on its opposite sides with a pair of separation structures DB that are opposite to each other in the second direction D2. For example, the pair of separation structures DB may be correspondingly provided on first boundary BD1 and the second boundary BD2 of the first single height cell SHC1. The separation structure DB may extend in the first direction D1 parallel to the gate electrodes GE. A pitch between the separation structure DB and its adjacent gate electrode GE may be the same as the first pitch.

The separation structure DB may penetrate the gate capping pattern GP and the gate electrode GE to extend into the first active pattern AP1 and the second active pattern AP2. The separation structure DB may penetrate an upper portion of each of the first active pattern AP1 and the second active pattern AP2. The separation structure DB may electrically separate an active region of each of the first single height cell SHC1 and the second single height cell SHC2 from an active region of another cell.

Active contacts AC may be provided to penetrate the first interlayer dielectric layer 110 and the second interlayer dielectric layer 120 to come into electrical connection with the first source/drain pattern SD1 and the second source/drain pattern SD2. A pair of active contacts AC may be correspondingly provided on opposite sides of the gate electrode GE. When viewed in a plan view, the active contact AC may have a bar shape that extends in the first direction D1.

The active contact AC may be a self-aligned contact. For example, the gate capping pattern GP and the gate spacer GS may be used to form the active contact AC in a self-alignment manner. The active contact AC may cover, for example, at least a portion of a sidewall of the gate spacer GS. The active contact AC may cover a portion of the top surface of the gate capping pattern GP.

A metal-semiconductor compound layer SC, such as a silicide layer, may be interposed between the active contact AC and the first source/drain pattern SD1 and between the active contact AC and the second source/drain pattern SD2. The active contact AC may be electrically connected through the metal-semiconductor compound layer SC to one of the first source/drain pattern SD1 and the second source/drain pattern SD2. For example, the metal-semiconductor compound layer SC may include at least one selected from titanium silicide, tantalum silicide, tungsten silicide, nickel silicide, and cobalt silicide.

Referring back to FIG. 5C, at least one active contact AC on the first single height cell SHC1 may electrically connect the first source/drain pattern SD1 of the first PMOSFET region PR1 to the second source/drain pattern SD2 of the first NMOSFET region NR1. The active contact AC may extend in the first direction D1 from the second source/drain pattern SD2 of the first NMOSFET region NR1 to the first source/drain pattern SD1 of the first PMOSFET region PR1.

The active contact AC may include a barrier metal BM and a fill metal FM on the barrier metal BM. The barrier metal BM may surround a surface of the fill metal FM except a top surface of the fill metal FM. For example, the fill metal FM may include at least one selected from molybdenum, tungsten, ruthenium, cobalt, and vanadium. The barrier metal BM may include a metal nitride layer. The metal nitride layer may include at least one selected from a titanium nitride (TiN) layer, a tantalum nitride (TaN) layer, a tungsten nitride (WN) layer, a nickel nitride (NiN) layer, a cobalt nitride (CON) layer, and a platinum nitride (PIN) layer.

Gate contacts GC may be provided to penetrate the third interlayer dielectric layer 130, the second interlayer dielectric layer 120, and the gate capping pattern GP to come into electrical connection with the gate electrodes GE. When viewed in a plan view, two gate contacts GC on the first single height cell SHC1 may be located to overlap the first PMOSFET region PR1. For example, two gate contacts GC on the first single height cell SHC1 may be provided on the first active pattern AP1 (see FIG. 5A). When viewed in a plan view, one gate contact GC on the first single height cell SHC1 may be located to overlap the first NMOSFET region NR1. For example, one gate contact GC on the first single height cell SHC1 may be provided on the second active pattern AP2 (see FIG. 5B).

The gate contact GC may be freely located with no limitation of position on the gate electrode GE. For example, the gate contacts GC on the second single height cell SHC2 may be correspondingly located on the second PMOSFET region PR2, the second NMOSFET region NR2, and the device isolation layer ST that fills the trench TR (see FIG. 4).

In an embodiment, referring to FIGS. 5A and 5B, an upper dielectric pattern UIP may fill an upper portion of the active contact AC, which upper portion is adjacent to the gate contact GC. The upper dielectric pattern UIP may have a bottom surface lower than a bottom surface of the gate contact GC. For example, the upper dielectric pattern UIP may cause the active contact AC adjacent to the gate contact GC to have a top surface lower than the bottom surface of the gate contact GC. Therefore, it may be possible to prevent a short-circuit resulting from contact between the gate contact GC and its adjacent active contact AC.

A first via VI1 may be provided on the active contact AC. The first via VI1 may have a top surface located at the same level as that of a top surface of the gate contact GC. In an embodiment, the first via VI1 and the gate contact GC may be formed at the same time. The first via VI1 and the gate contact Gc may include the same material.

The gate contact GC may include no barrier metal. The gate contact GC may be formed of single metal. The gate contact GC may include at least one selected from molybdenum, tungsten, ruthenium, cobalt, and vanadium. Similarly, the gate contact GC, the first via VI1 may include no barrier metal. The first via VI1 may include the same metal as that of the gate contact GC.

A first metal layer M1 may be provided in the third interlayer dielectric layer 130. For example, the first metal layer M1 may include a first power line M1_R1, a second power line M1_R2, a third power line M1_R3, and first wiring lines M1_I. The lines M1_R1, M1_R2, M1_R3, and M1_I of the first metal layer M1 may extend in parallel to each other in the second direction D2.

For example, the first power line M1_R1 and the second power line M1_R2 may be correspondingly provided on the third boundary BD1 and the fourth boundary BD2 of the first single height cell SHC1. The first power line M1_R1 may extend in the second direction D2 along the third boundary BD3. The second power line M1_R2 may extend in the second direction D2 along the fourth boundary BD4.

The first wiring lines M1_I of the first metal layer M1 may be arranged at a second pitch along the first direction D1. The second pitch may be less than the first pitch. Each of the first wiring lines M1_I may have a line-width less than that of each of the first power line M1_R1, second power line M1_R2, and third power line M1_R3.

The first via VI1 may electrically connect the active contact AC to one of the lines M1_R1, M1_R2, M1_R3, and M1_I of the first metal layer M1. The gate electrode GE may be electrically connected through the gate contact GC to one of the lines M1_R1, M1_R2, M1_R3, and M1_I of the first metal layer M1.

A certain line and its underlying first via VI1 of the first metal layer M1 may be formed by individual processes. For example, the certain line and its underlying first via VI1 of the first metal layer M1 may each be formed by a single damascene process. A sub-20 nm process may be employed to fabricate a semiconductor device according to some embodiments.

A second metal layer M2 may be provided in the fourth interlayer dielectric layer 140. The second metal layer M2 may include a plurality of second wiring lines M2_I. The second wiring lines M2_I of the second metal layer M2 may each have a linear or bar shape that extends in the first direction D1. For example, the second wiring lines M2_I may extend in parallel to each other in the first direction D1.

The second metal layer M2 may further include second vias VI2 that are correspondingly provided below the second wiring lines M2_I. A certain line of the first metal layer M1 may be electrically through the second via VI2 to a corresponding line of the second metal layer M2. For example, a wiring line and its underlying second via VI2 of the second metal layer M2 may be simultaneously formed in a dual damascene process.

The first metal layer M1 and the second metal layer M2 may have their wiring lines that include the same or different conductive materials. For example, the first metal layer M1 and the second metal layer M2 may have their lines including at least one metal selected from copper, ruthenium, aluminum, tungsten, molybdenum, and cobalt. Other metal layers (e.g., M3, M4, M5, etc.) may be additionally stacked on the fourth interlayer dielectric layer 140. Each of the stacked metal layers may include wiring lines for routing between cells.

The first channel pattern CH1 will be representatively discussed in detail below with reference to FIG. 6. In an embodiment, each of the first semiconductor pattern SP1, second semiconductor pattern SP2, and third semiconductor pattern SP3 may include semiconductor layers SEL and a superlattice layer EPL sandwiched between the semiconductor layers SEL.

One of the semiconductor layers SEL may be provided on a lower portion of a corresponding one of the semiconductor patterns SP1, SP2, and SP3 and may be in direct contact with the gate dielectric layer GI. Another of the semiconductor layers SEL may be provided on an upper portion of a corresponding one of the semiconductor patterns SP1, SP2, and SP3 and may be in direct contact with the gate dielectric layer GI. The superlattice layer EPL may be provided on a central portion of a corresponding one of the semiconductor patterns SP1, SP2, and SP3 and may be spaced apart from the gate dielectric layer GI. The superlattice layer EPL may connect neighboring first source/drain patterns SD1 to each other.

In an embodiment, one of the semiconductor layers SEL may have a first thickness TK1, and another of the semiconductor layers SEL may have a second thickness TK2. The superlattice layer EPL may have a third thickness TK3. The third thickness TK3 may be less than the first thickness TK1. The third thickness TK3 may be less than the second thickness TK2. For example, the third thickness TK3 may range from about 1 nm to about 10 nm.

When the superlattice layer EPL has a thickness greater than about 10 nm, a carrier mobility may be relatively small. When the superlattice layer EPL has a thickness less than about 1 nm, an unclear interface may be provided between the semiconductor layer SEL and the superlattice layer EPL and thus it may be difficult to give a superlattice structure to a channel.

For example, the semiconductor layers SEL may include monocrystalline silicon (Si). The superlattice layer EPL may include, without limitation, a material capable of allowing the semiconductor patterns SP1, SP2, and SP3 to have a superlattice structure. The superlattice layer EPL may include at least one crystalline semiconductor material selected from germanium (Ge), gallium arsenide (GaAs), indium arsenide (InAs), indium antimonide (InSb), and indium phosphide (InP).

The superlattice layer EPL may have carrier mobility greater than that of the semiconductor layer SEL. Thus, the semiconductor patterns SP1, SP2, and SP3 including the superlattice layer EPL may achieve a relatively low channel resistance.

According to some embodiments, the superlattice layer EPL of the first semiconductor pattern SP1 may have a first length LE1 in the second direction D2. The superlattice layer EPL of the second semiconductor pattern SP2 may have a second length LE2 in the second direction D2. The first length LE1 and the second length LE2 may be different from each other. For example, the first length LE1 may be greater than the second length LE2.

In an embodiment, the superlattice layers EPL in the semiconductor patterns SP1, SP2, and SP3, or nano-sheets, may have their lengths that decrease in a direction from a lower tier to an upper tier. This may be caused by the fact that nano-sheets of the first channel pattern CH1 may have their lengths that decrease in a direction from a lower tier to an upper tier, and therefore the lengths of the superlattice layers EPL may also decrease in a direction from a lower tier to an upper tier.

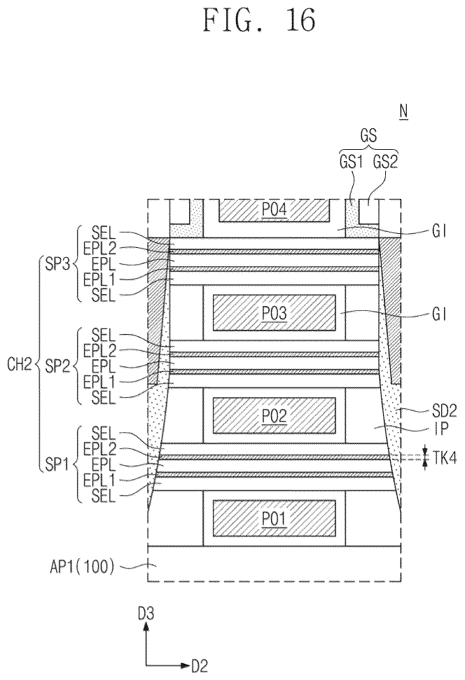

FIG. 6 depicts a superlattice channel applied to PMOSFET, but the superlattice layer EPL discussed in FIG. 6 may also be identically applied to the second channel pattern CH2 of NMOSFET. FIG. 16 depicts by way of example a superlattice channel applied to NMOSFET according to some embodiments.

In a semiconductor device according some embodiments, the superlattice layer EPL may be provided in a nano-sheet or a channel, and thus the nano-sheet may have a superlattice structure. Accordingly, a carrier mobility of the nano-sheet may increase to reduce a channel resistance. In addition, there may be an improvement in short-channel effect of a three dimensional field effect transistor (FET) according to the present inventive concepts.

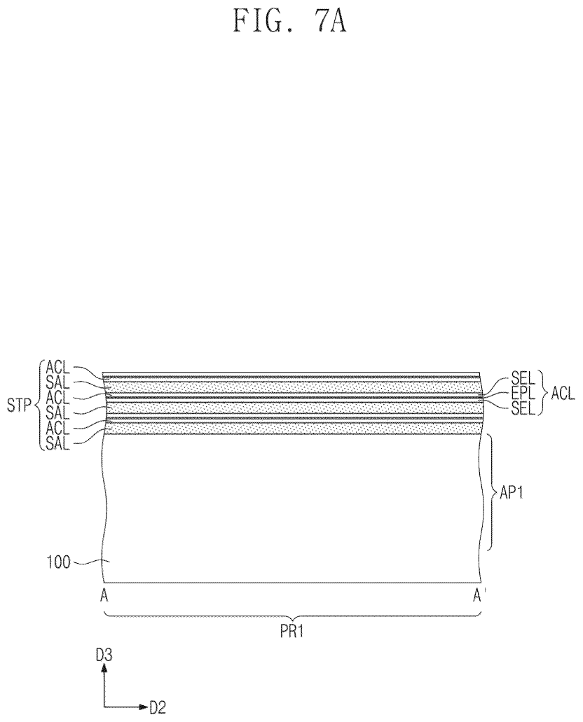

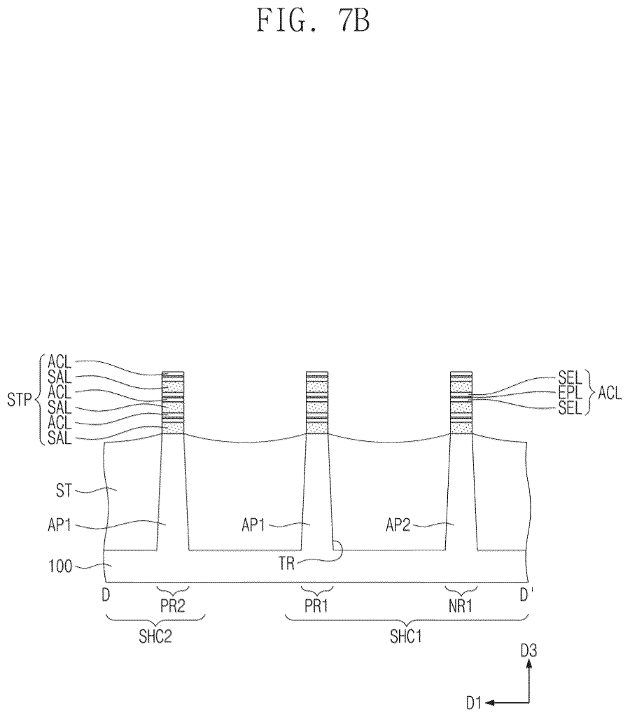

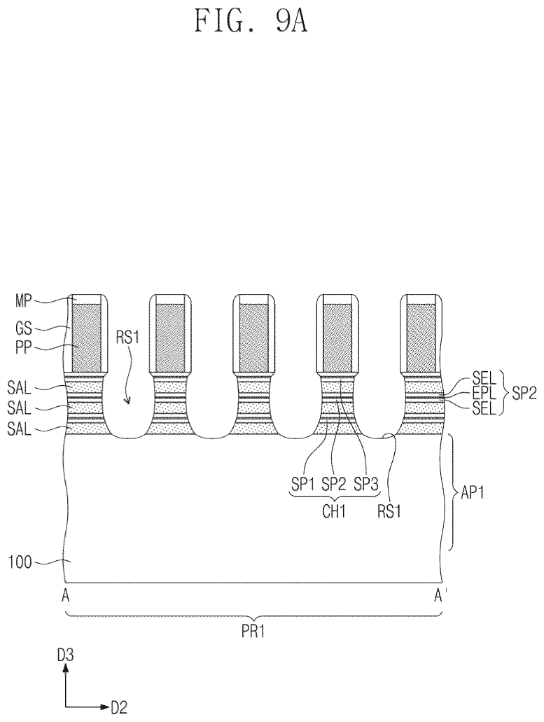

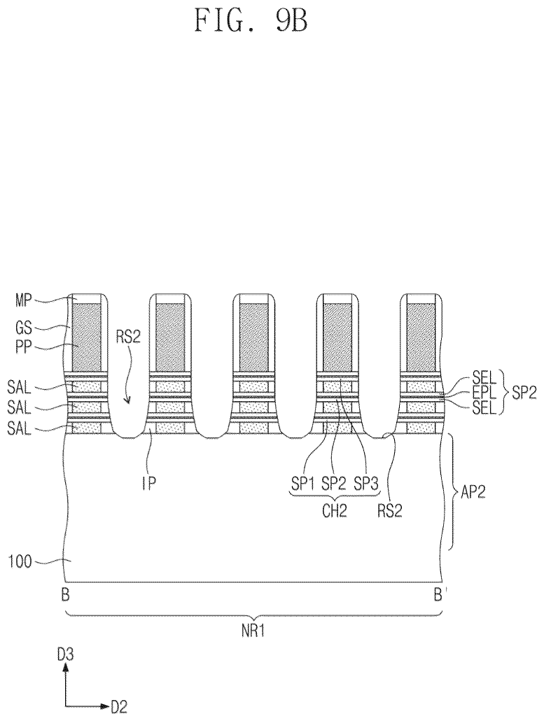

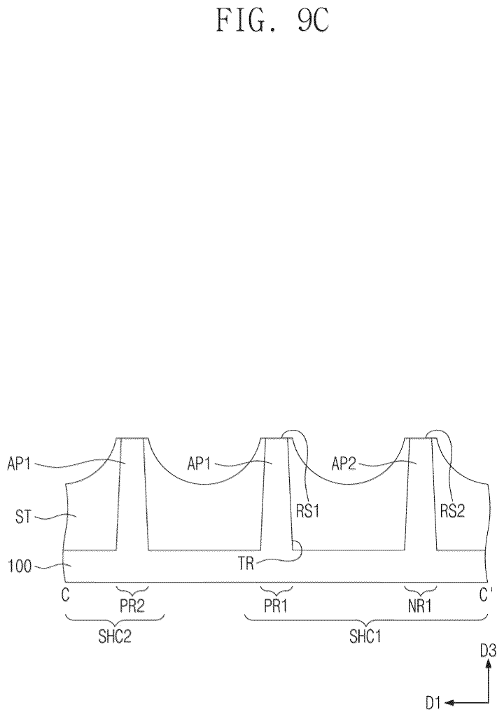

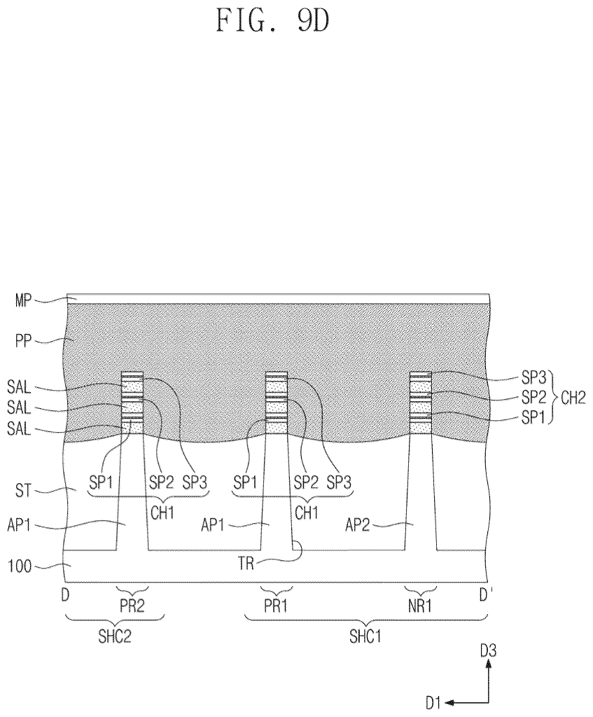

FIGS. 7A to 13D illustrate cross-sectional views showing a method of fabricating a semiconductor device according to some embodiments. In detail, FIGS. 7A, 8A, 9A, 10A, 11A, 12A, and 13A illustrate cross-sectional views taken along line A-A′ of FIG. 4. FIGS. 9B, 10B, 11B, 12B, and 13B illustrate cross-sectional views taken along line B-B′ of FIG. 4. FIGS. 9C, 10C, 11C, 12C, and 13C illustrate cross-sectional views taken along line C-C′ of FIG. 4. FIGS. 7B, 8B, 9D, 10D, 11D, 12D, and 13D illustrate cross-sectional views taken along line D-D′ of FIG. 4.

Referring to FIGS. 7A and 7B, a substrate 100 may be provided which includes first PMOSFET region PR1 and the second PMOSFET region PR2 and first NMOSFET region NR1 and the second NMOSFET region NR2. Active layers ACL and sacrificial layers SAL may be alternately formed on the substrate 100. The active layers ACL may include one of silicon (Si), germanium (Ge), and silicon-germanium (SiGe), and the sacrificial layers SAL may include another of silicon (Si), germanium (Ge), and silicon-germanium (SiGe).

The sacrificial layer SAL may include a material having an etch selectivity with respect to the active layer ACL. For example, the active layers ACL may include silicon (Si), and the sacrificial layers SAL may include silicon-germanium (SiGe). Each of the sacrificial layers SAL may have a germanium concentration of about 10 at % to about 30 at %.

According to some embodiments, the formation of the active layer ACL may include forming semiconductor layers SEL, and forming a superlattice layer EPL between the semiconductor layers SEL.

Each of the semiconductor layer SEL and the superlattice layer EPL may be formed by an epitaxial growth process. Each of the semiconductor layer SEL and the superlattice layer EPL may be formed of a crystalline semiconductor material. For example, the semiconductor layer SEL may be formed of monocrystalline silicon (Si).

The superlattice layer EPL may be grown on the semiconductor layer SEL. The superlattice layer EPL may include at least one crystalline semiconductor material selected from the group consisting of Ge, GaAs, InAs, InSb, and InP. The superlattice layer EPL may be formed to have a thickness less than that of the semiconductor layer SEL. Subsequently, a semiconductor layer SEL may be epitaxially grown again on the superlattice layer EPL. The superlattice layer EPL may be interposed between the semiconductor layers SEL, and thus the active layer ACL may have a superlattice structure.

Mask patterns may be correspondingly formed on the first PMOSFET region PR1 and the second PMOSFET region PR2 and the first NMOSFET region NR1 and the second NMOSFET region NR2 of the substrate 100. The mask pattern may have a linear or bar shape that extends in a second direction D2.

A patterning process may be performed in which the mask patterns are used as an etching mask to form a trench TR that defines a first active pattern AP1 and a second active pattern AP2. The first active pattern AP1 may be formed on each of the first PMOSFET region PR1 and the second PMOSFET region PR2. The second active pattern AP2 may be formed on each of the first NMOSFET region NR1 and the second NMOSFET region NR2.

A stack pattern STP may be formed on each of the first active pattern AP1 and the second active pattern AP2. The stack pattern STP may include the active layers ACL and the sacrificial layers SAL that are alternately stacked. During the patterning process, the stack pattern STP may be formed together with the first active pattern AP1 and the second active pattern AP2.

A device isolation layer ST may be formed to fill the trench TR. For example, a dielectric layer may be formed on an entire surface of the substrate 100 to cover the stack patterns STP and the first active pattern AP1 and the second active pattern AP2. The dielectric layer may be recessed until the stack patterns STP are exposed, and thus the device isolation layer ST may be formed.

The device isolation layer ST may include a dielectric material, such as a silicon oxide layer. The stack patterns STP may be exposed upwardly from the device isolation layer ST. For example, the stack patterns STP may vertically protrude upwards from the device isolation layer ST.

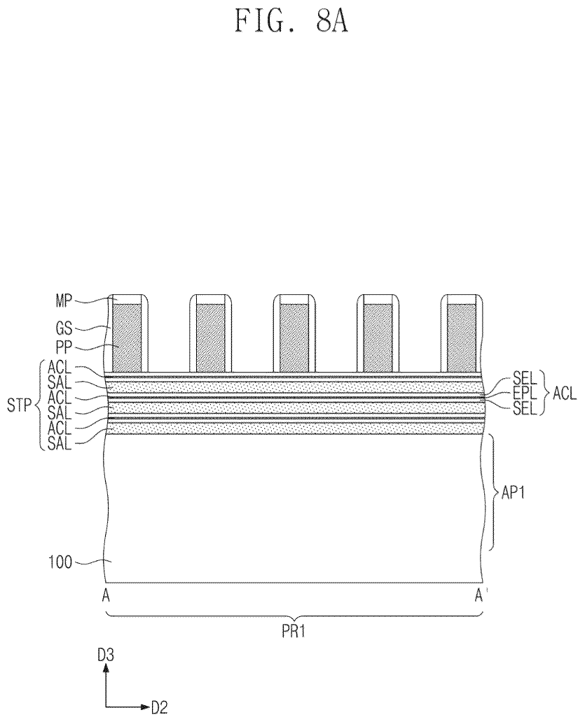

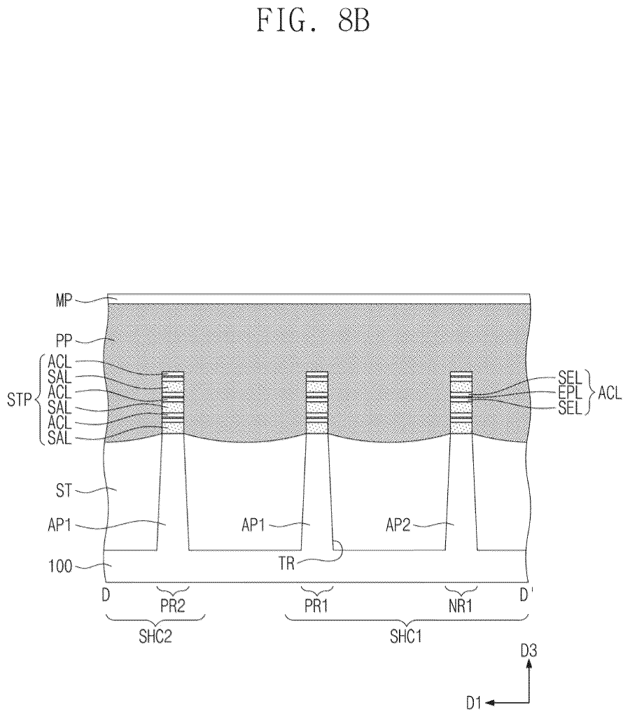

Referring to FIGS. 8A and 8B, sacrificial patterns PP may be formed on the substrate 100, running across the stack patterns STP. Each of the sacrificial patterns PP may be formed to have a linear or bar shape that extends in a first direction D1. The sacrificial patterns PP may be arranged at a first pitch along the second direction D2.

For example, the formation of the sacrificial patterns PP may include forming a sacrificial layer on the entire surface of the substrate 100, forming hardmask patterns MP on the sacrificial layer, and using the hardmask patterns MP as an etching mask to pattern the sacrificial layer. The sacrificial layer may include, for example, polysilicon.

A pair of gate spacers GS may be formed on opposite sidewalls of each of the sacrificial patterns PP. The formation of the gate spacers GS may include conformally forming a gate spacer layer on the entire surface of the substrate 100 and anisotropically etching the gate spacer layer. In an embodiment, the gate spacer GS may be a multiple layer including at least two layers.

Referring to FIGS. 9A to 9D, first recesses RS1 may be formed in the stack pattern STP on the first active pattern AP1. Second recesses RS2 may be formed in the stack pattern STP on the second active pattern AP2. During the formation of the first and second recesses RS1 and RS2, the device isolation layer ST may further be recessed on opposite sides of each of the first active pattern AP1 and the second active pattern AP2 (see FIG. 9C).

For example, the hardmask patterns MP and the gate spacers GS may be used as an etching mask such that the stack pattern STP on the first active pattern AP1 may be etched to form the first recesses RS1. The first recess RS1 may be formed between a pair of sacrificial patterns PP.

The second recesses RS2 in the stack pattern STP on the second active pattern AP2 may be formed by the same method used for the formation of the first recesses RS1. The formation of the second recess RS2 may further include forming an inner spacer IP in a zone where the sacrificial layer SAL is recessed.

The active layers ACL may be formed into first semiconductor pattern SP1, second semiconductor pattern SP2, and third semiconductor pattern SP3 that are sequentially stacked between neighboring first recesses RS1. The active layers ACL may be formed into first semiconductor pattern SP1, second semiconductor pattern SP2, and third semiconductor pattern SP3 that are sequentially stacked between neighboring second recesses RS2. A first channel pattern CH1 may be constituted by the first semiconductor pattern SP1, second semiconductor pattern SP2, and third semiconductor pattern SP3 between neighboring first recesses RS1. A second channel pattern CH2 may be constituted by the first semiconductor pattern SP1, second semiconductor pattern SP2, and third semiconductor pattern SP3 between neighboring second recesses RS2.

Each of the first semiconductor pattern SP1, second semiconductor pattern SP2, and third semiconductor pattern SP3 may include the superlattice layer EPL discussed above. For example, each of the first semiconductor pattern SP1, second semiconductor pattern SP2, and third semiconductor pattern SP3 may include the semiconductor layers SEL and the superlattice layer EPL between the semiconductor layers SEL. Thus, each of the first semiconductor pattern SP1, second semiconductor pattern SP2, and third semiconductor pattern SP3 may be formed of a nano-sheet having a superlattice structure.

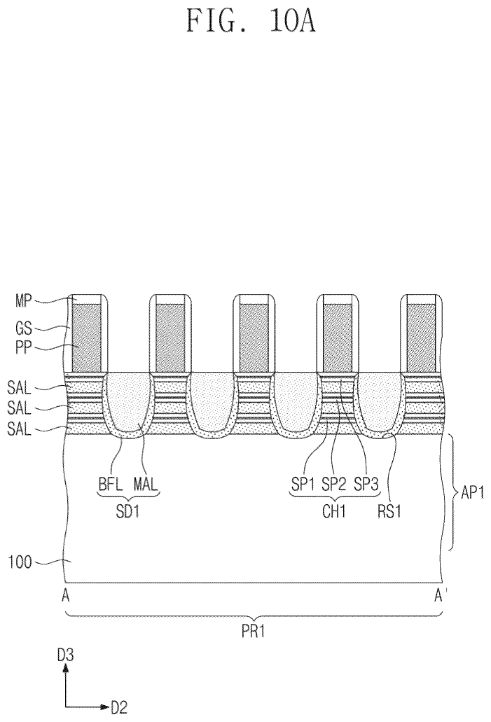

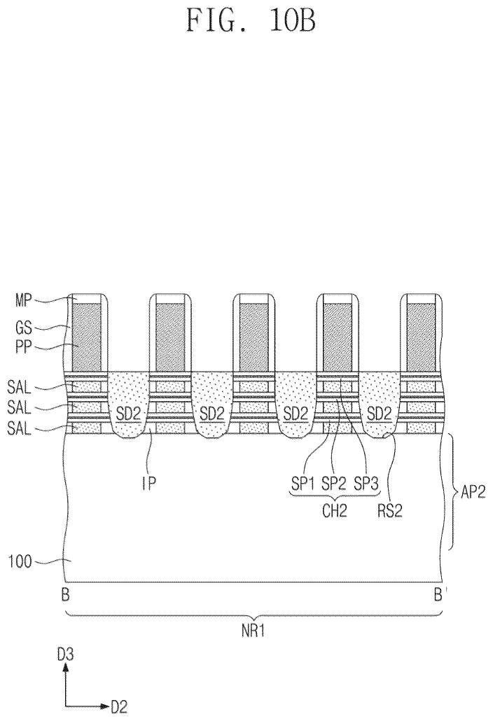

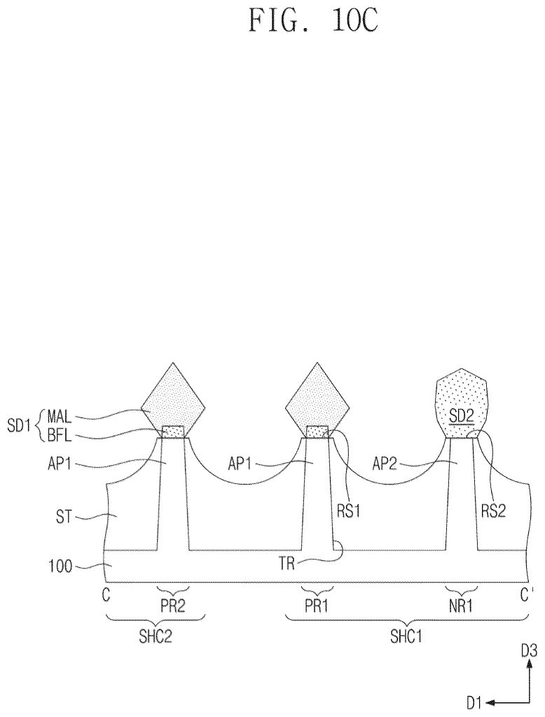

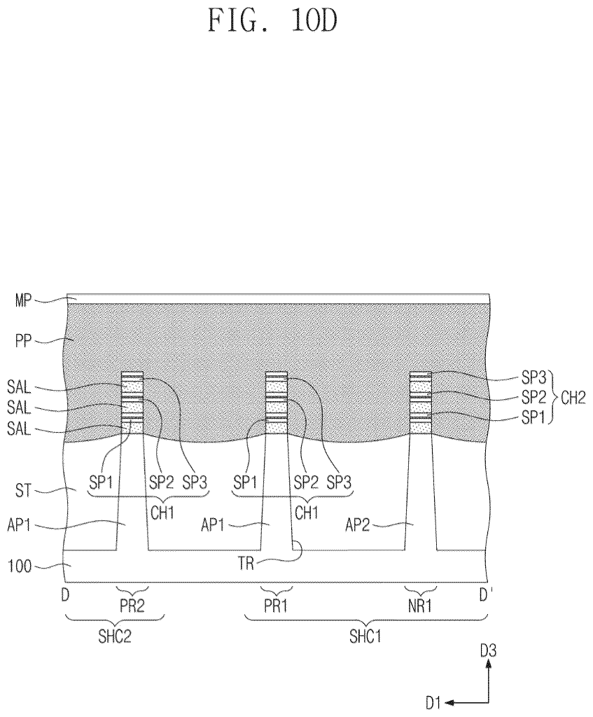

Referring to FIGS. 10A to 10D, first source/drain patterns SD1 may be correspondingly formed in the first recesses RS1. For example, a first selective epitaxial growth (SEG) process may be performed in which an inner wall of the first recess RS1 is used as a seed layer to form a buffer layer BFL. The buffer layer BFL may be grown from a seed, or the substrate 100 and the first semiconductor pattern SP1, second semiconductor pattern SP2, and third semiconductor pattern SP3 exposed by the first recess RS1. For example, the first SEG process may include chemical vapor deposition (CVD) or molecular beam epitaxy (MBE).

The buffer layer BFL may include a semiconductor element (e.g., SiGe) whose lattice constant is greater than that of a semiconductor element of the substrate 100. The buffer layer BFL may contain germanium (Ge) whose concentration is relatively low. In another example, the buffer layer BFL may not include germanium (Ge), but include only silicon (Si). The germanium concentration of the buffer layer BFL may range from about 0 at % to about 10 at %.

The buffer layer BFL may undergo a second SEG process to form a main layer MAL. The main layer MAL may be formed to completely fill the first recess RS1. The main layer MAL may contain germanium (Ge) whose concentration is relatively high. For example, the germanium concentration of the main layer MAL may range from about 30 at % to about 70 at %.

During the formation of the buffer layer BFL and the main layer MAL, impurities (e.g., boron, gallium, or indium) may be in-situ implanted to allow the first source/drain pattern SD1 to have a p-type conductivity. Alternatively, after the formation of the first source/drain pattern SD1, impurities may be implanted into the first source/drain pattern SD1.

Second source/drain patterns SD2 may be correspondingly formed in the second recesses RS2. For example, a third selective epitaxial growth (SEG) process may be performed in which an inner wall of the second recess RS2 is used as a seed to form the second source/drain pattern SD2. For example, the second source/drain pattern SD2 may include the same semiconductor element (e.g., Si) as that of the substrate 100.

During the formation of the second source/drain pattern SD2, impurities (e.g., phosphorus, arsenic, or antimony) may be in-situ implanted to allow the second source/drain pattern SD2 to have an n-type conductivity type. Alternatively, after the formation of the second source/drain pattern SD2, impurities may be implanted into the second source/drain pattern SD2.

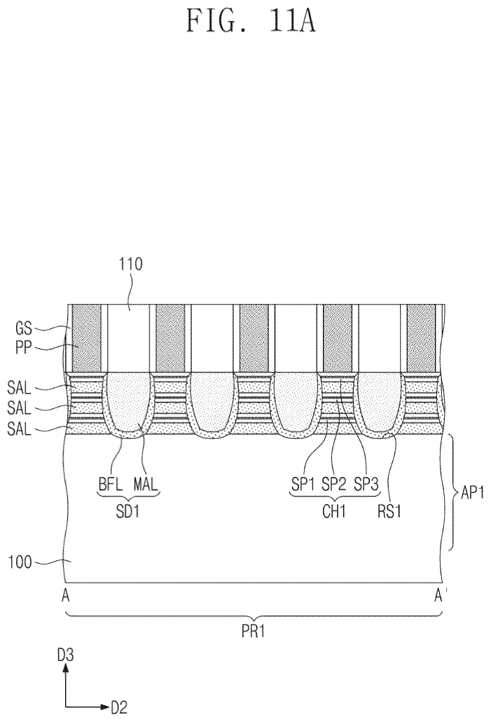

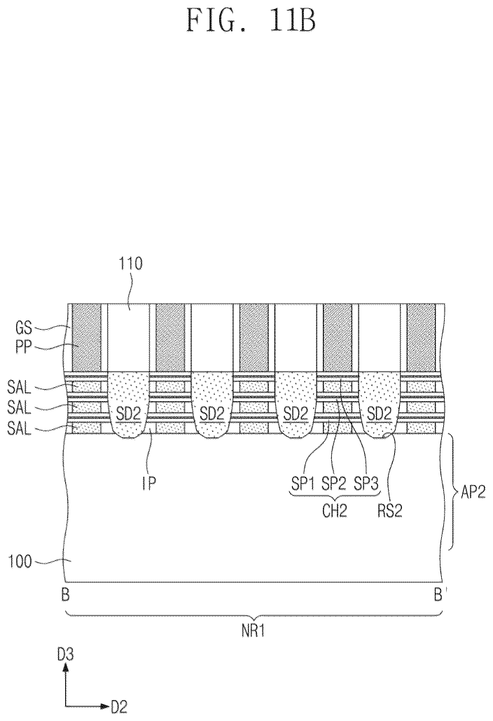

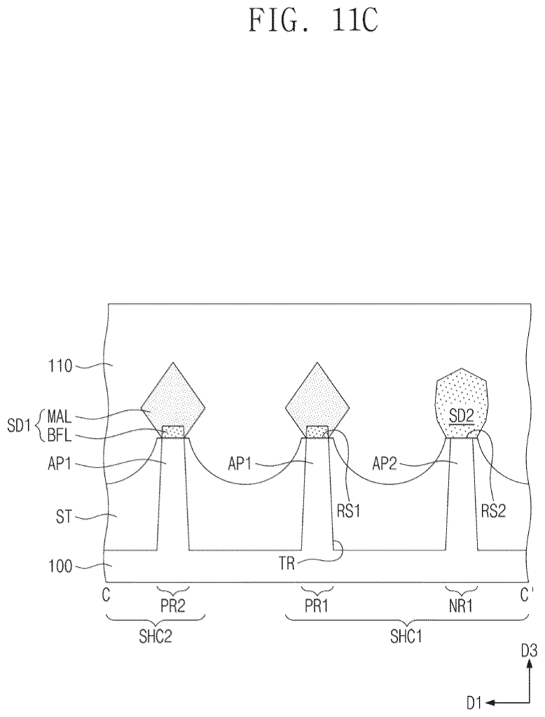

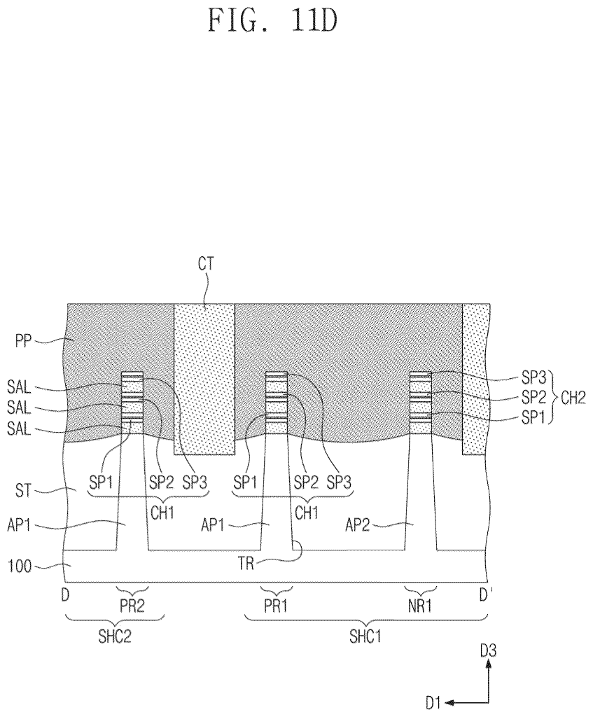

Referring to FIGS. 11A to 11D, a first interlayer dielectric layer 110 may be formed to cover the first source/drain pattern SD1 and the second source/drain pattern SD2, the hardmask patterns MP, and the gate spacers GS. For example, the first interlayer dielectric layer 110 may include a silicon oxide layer.

The first interlayer dielectric layer 110 may be planarized until top surfaces of the sacrificial patterns PP are exposed. An etch-back or chemical mechanical polishing (CMP) process may be employed to planarize the first interlayer dielectric layer 110. The hardmask patterns MP may all be removed during the planarization process. As a result, the first interlayer dielectric layer 110 may have a top surface coplanar with those of the sacrificial patterns PP and those of the gate spacers GS.

A photolithography process may be used to selectively open one region of the sacrificial pattern PP. For example, it may be possible to selectively open a portion of the sacrificial pattern PP on the third boundary BD1 and the fourth boundary BD2 of the first single height cell SHC1. The opened portion of the sacrificial pattern PP may be selectively etched and removed. A space where the sacrificial pattern PP is removed may be filled with a dielectric material to form a gate cutting pattern CT.

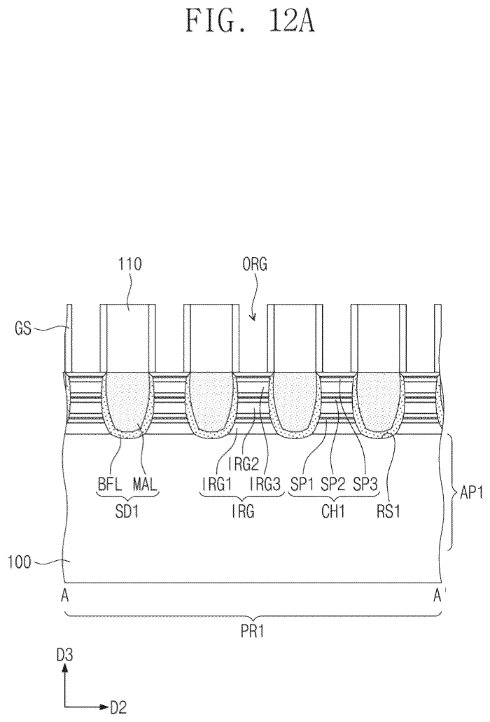

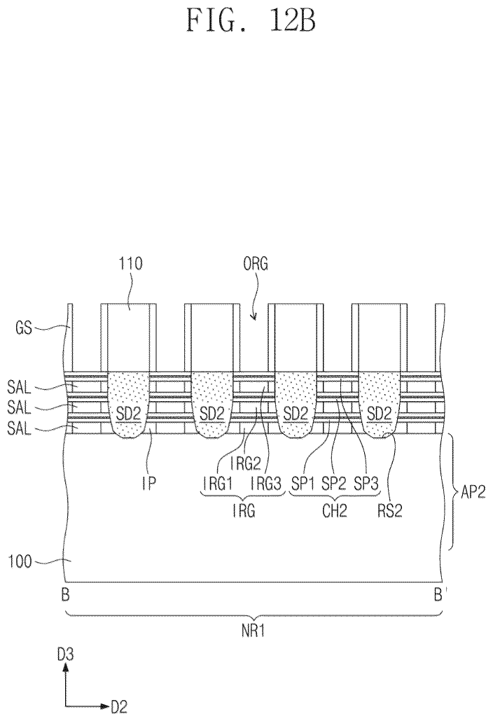

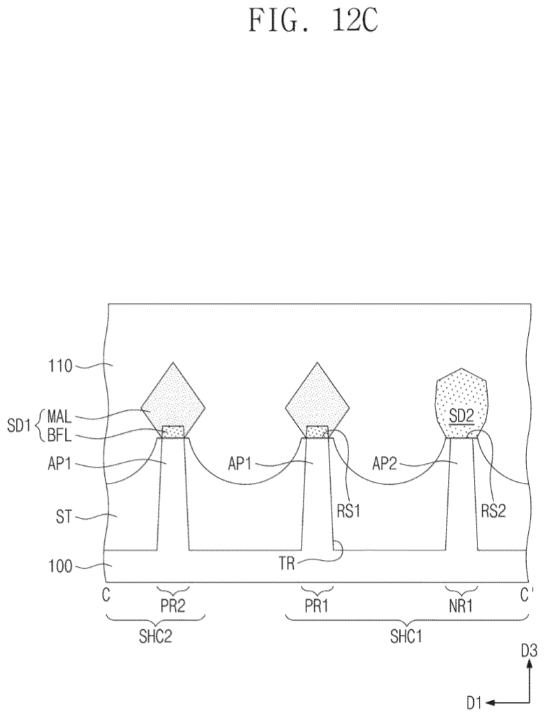

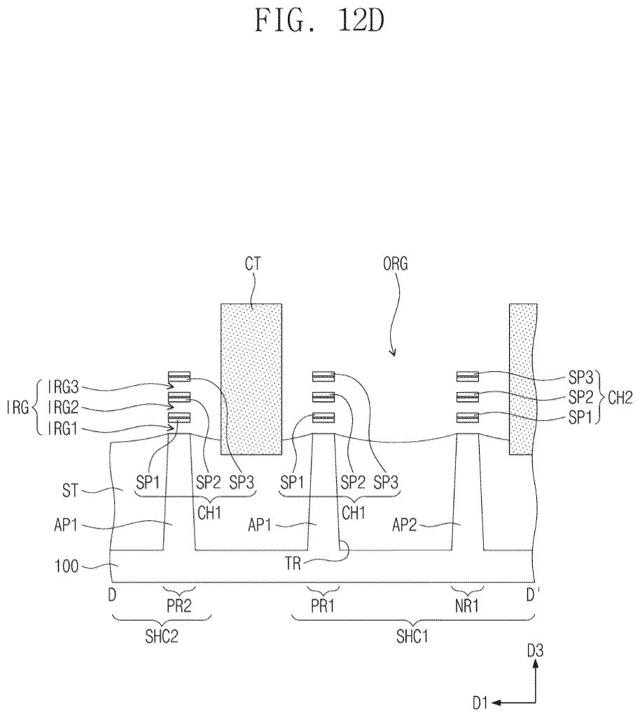

Referring to FIGS. 12A and 12D, the exposed sacrificial patterns PP may be selectively removed. The removal of the sacrificial patterns PP may form an outer region ORG that exposes the first channel pattern CH1 and second channel pattern CH2 (see FIG. 12D). The removal of the sacrificial patterns PP may include performing a wet etching process using an etchant that selectively etches polysilicon.

The sacrificial layers SAL exposed through the outer region ORG may be selectively removed to form inner regions IRG (see FIG. 12D). For example, an etching process that selectively etches the sacrificial layers SAL may be performed such that only the sacrificial layers SAL may be removed while leaving the first semiconductor pattern SP1, second semiconductor pattern SP2, and third semiconductor pattern SP3. The etching process may have a high etch rate with respect to silicon-germanium having a relatively high germanium concentration. For example, the etching process may have a high etch rate with respect to silicon-germanium whose germanium concentration is greater than about 10 at %.

During the etching process, the sacrificial layers SAL may be removed from the first PMOSFET region PR1 and the second PMOSFET region PR2 and from the first NMOSFET region NR1 and the second NMOSFET region NR2. The etching process may be a wet etching process. An etching material used for the etching process may etch the sacrificial layer SAL whose germanium concentrate is relatively high. During the etching process, the first source/drain pattern SD1 on the first PMOSFET region PR1 and the second PMOSFET region PR2 may be protected by the buffer layer BFL whose germanium concentration is relatively low.

Referring back to FIG. 12D, as the sacrificial layers SAL are selectively removed, the stacked first semiconductor pattern SP1, second semiconductor pattern SP2, and third semiconductor pattern SP3 may remain on each of the first active pattern AP1 and the second active pattern AP2. The removal of the sacrificial layers SAL may form first, second, and third inner regions IRG1, IRG3, and IRG3.

For example, the first inner region IRG1 may be formed between the active pattern AP1 or AP2 and the first semiconductor pattern SP1, the second inner region IRG2 may be formed between the first semiconductor pattern SP1 and the second semiconductor pattern SP2, and the third inner region IRG3 may be formed between the second semiconductor pattern SP2 and the third semiconductor pattern SP3.

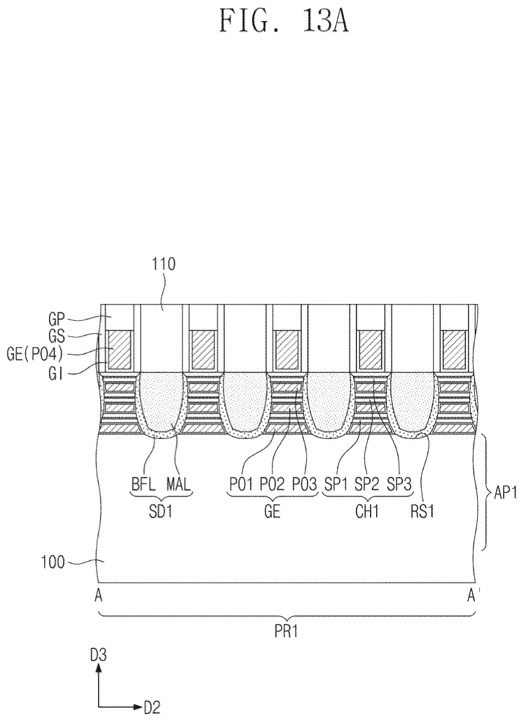

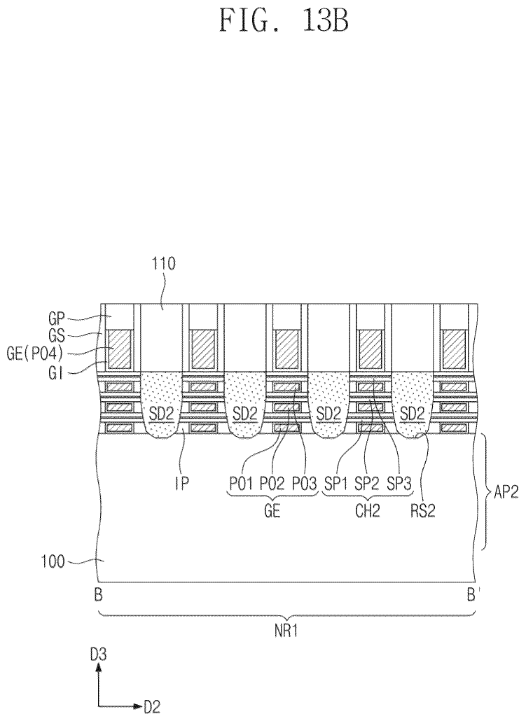

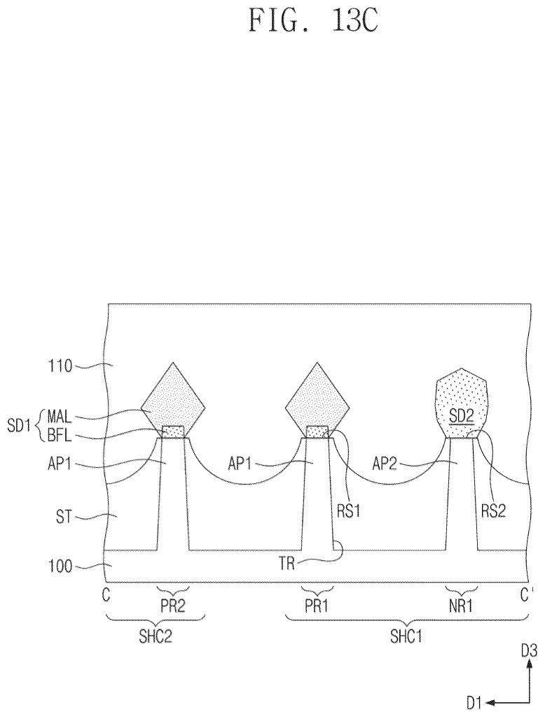

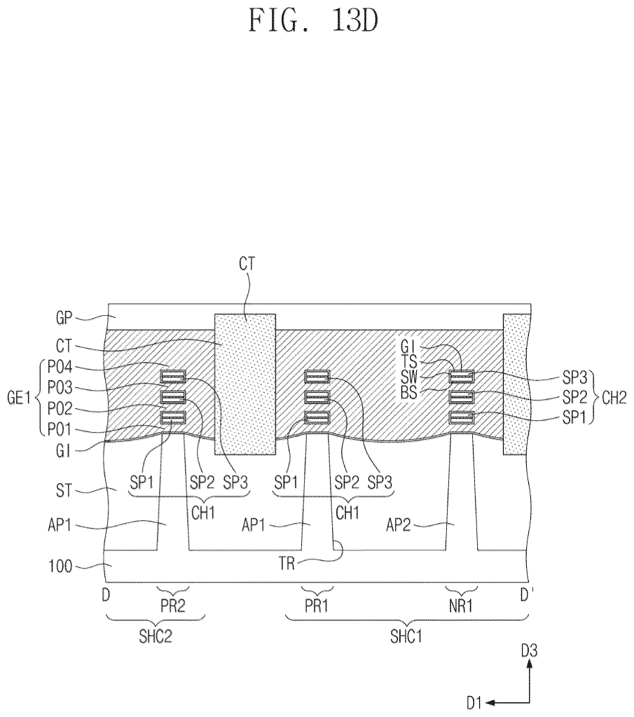

Referring to FIGS. 13A to 13D, a gate dielectric layer GI may be conformally formed on the exposed first semiconductor pattern SP1, second semiconductor pattern SP2, and third semiconductor pattern SP3. A gate electrode GE may be formed on the gate dielectric layer GI. The gate electrode GE may include first inner electrode PO1, second inner electrode PO2, and third inner electrode PO3 that are respectively formed in the first inner region IRG1, the second inner region IRG2, and third inner region IRG3, and may also include an outer electrode PO4 formed in the outer region ORG.

The gate electrode GE may be recessed to have a reduced height. While the gate electrode GE is recessed, an upper portion of the gate cutting pattern CT may also be slightly recessed. A gate capping pattern GP may be formed on the recessed gate electrode GE.

A separation structure DB may be formed to penetrate the gate electrode GE. The separation structure DB may extend from the gate capping pattern GP through the gate electrode GE into the active pattern AP1 or AP2. The separation structure DB may include a dielectric material, such as a silicon oxide layer or a silicon nitride layer.

Referring back to FIGS. 4 and 5A to 5D, a second interlayer dielectric layer 120 may be formed on the first interlayer dielectric layer 110. The second interlayer dielectric layer 120 may include a silicon oxide layer. Active contacts AC may be formed to penetrate the second interlayer dielectric layer 120 and the first interlayer dielectric layer 110 to come into electrical connection with the first source/drain pattern SD1 and the second source/drain pattern SD2.

The formation of the active contact AC may include forming a barrier metal BM and forming a fill metal FM on the barrier metal BM. The barrier metal BM may be conformally formed, and may include a metal layer and a metal nitride layer. The fill metal FM may include metal whose resistance is relatively low.

A third interlayer dielectric layer 130 may be formed on the second interlayer dielectric layer 120. A gate contact GC may be formed to penetrate the third interlayer dielectric layer 130, the second interlayer dielectric layer 120, and the gate capping pattern GP to come into connection with the gate electrode GE. A first via VI1 may be formed to penetrate the third interlayer dielectric layer 130 to come into connection with the active contact AC. The gate contact GC and the first via VI1 may be formed together with each other.

A first metal layer M1 may be formed in the third interlayer dielectric layer 130. For example, in an upper portion of the third interlayer dielectric layer 130, lines M1_R1, M1_R2, M1_R3, and M1_I may be formed to correspondingly be connected to the gate contact GC and the first via VI1. A fourth interlayer dielectric layer 140 may be formed on the third interlayer dielectric layer 130. A second metal layer M2 may be formed in the fourth interlayer dielectric layer 140.

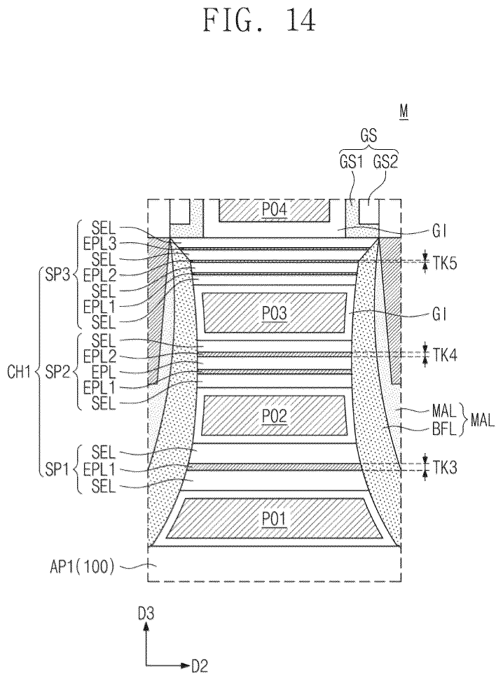

FIGS. 14 to 16 illustrate enlarged views showing a semiconductor device according to some embodiments. In the embodiments that follow, a detailed description of technical features repetitive to those discussed above with reference to FIGS. 4 to 6 will be omitted, and a difference thereof will be discussed in detail.

Referring to FIG. 14, there may be a difference in the number of the superlattice layers EPL in the first semiconductor pattern SP1, second semiconductor pattern SP2, and third semiconductor pattern SP3. For example, the first semiconductor pattern SP1 may include a semiconductor layer SEL, a first superlattice layer EPL1, and a semiconductor layer SEL that are sequentially stacked. One superlattice layer EPL may be present in the first semiconductor pattern SP1.

The second semiconductor pattern SP2 may include a semiconductor layer SEL, a first superlattice layer EPL1, a semiconductor layer SEL, a second superlattice layer EPL2, and a semiconductor layer SEL that are sequentially stacked. Two superlattice layers EPL may be present in the second semiconductor pattern SP2.

The third semiconductor pattern SP3 may include a semiconductor layer SEL, a first superlattice layer EPL1, a semiconductor layer SEL, a second superlattice layer EPL2, a semiconductor layer SEL, a third superlattice layer EPL3, and a semiconductor layer SEL that are sequentially stacked. Three superlattice layers EPL may be present in the third semiconductor pattern SP3.

The superlattice layers EPL in the first semiconductor pattern SP1, second semiconductor pattern SP2, and third semiconductor pattern SP3 may have different thicknesses from each other. The superlattice layer EPL in the first semiconductor pattern SP1 may have a third thickness TK3. The superlattice layer EPL in the second semiconductor pattern SP2 may have a fourth thickness TK4. The superlattice layer EPL in the third semiconductor pattern SP3 may have a fifth thickness TK5. For example, the fourth thickness TK4 may be less than the third thickness TK3. The fifth thickness TK5 may be less than the fourth thickness TK4.

The greater number of the superlattice layer EPL included in a nano-sheet or the semiconductor pattern SP1 to SP3, the higher mobility of carriers in the nano-sheet. In contrast, the increase in the number of the superlattice layer EPL in the nano-sheet may cause an increase in process difficulty and process cost. In addition, the increase in the number of the superlattice layer EPL in the nano-sheet may induce an increase in leakage current.

A higher amount of current may flow at an upper tier among the stacked semiconductor patterns SP1 to SP3. For example, a higher amount of current may flow in the third semiconductor pattern SP3 than in the first semiconductor pattern SP1. Therefore, compared to the first semiconductor pattern SP1, the third semiconductor pattern SP3 may have a greater effect on electrical properties of a semiconductor device.

According to the embodiment, there may be an increase in the number of the superlattice layer EPL in a nano-sheet at an upper tier, and a reduction in the number of the superlattice layer EPL in a nano-sheet at a lower tier. Accordingly, it may be possible to simultaneously improve electrical properties and process efficiency of a semiconductor device.

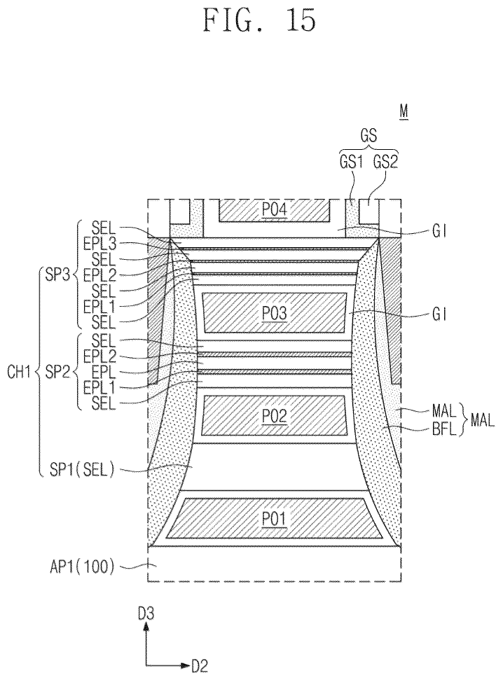

Referring to FIG. 15, the superlattice layer EPL may be omitted from a nano-sheet at a lowermost tier or from the first semiconductor pattern SP1. The first semiconductor pattern SP1 may include only the semiconductor layer SEL formed of monocrystalline silicon (Si). Even when the superlattice layer EPL is absent in the first semiconductor pattern SP1, electrical properties of devices may not be significantly affected. In addition, as the superlattice layer EPL is omitted from the first semiconductor pattern SP1, it may be possible to prevent a leakage current that is easily produced in the first semiconductor pattern SP1.

Referring to FIGS. 6 and 16, there are illustrated the first channel pattern CH1 of PMOSFET and the second channel pattern CH2 of NMOSFET. The first channel pattern CH1 may be same as that discussed above with reference to FIG. 6.

The number of the superlattice layer EPL in the semiconductor patterns SP1 to SP3 of the second channel pattern CH2 may be different from that of the superlattice layer EPL in the semiconductor patterns SP1 to SP3 of the first channel pattern CH1.

For example, each of the semiconductor patterns SP1 to SP3 of the second channel pattern CH2 may include a semiconductor layer SEL, a first superlattice layer EPL1, a semiconductor layer SEL, a second superlattice layer EPL2, and a semiconductor layer SEL that are sequentially stacked. Two superlattice layers EPL may be present in each of the semiconductor patterns SP1 to SP3 of the second channel pattern CH2. According to another embodiment, one superlattice layer EPL may be present in each of the semiconductor patterns SP1 to SP3 of the first channel pattern CH1 (see FIG. 6).

In an embodiment, the number of the superlattice layer EPL in a nano-sheet may have a greater effect on NMOSFET in which electrons serve as carriers than on PMOSFET in which holes serve as carriers. Therefore, the number of the superlattice layer EPL may be greater in the nano-sheet of NMOSFET than in the nano-sheet of PMOSFET. Accordingly, it may be possible to simultaneously improve electrical properties and process efficiency of devices.

In another embodiment, the number of the superlattice layer EPL may be greater in the nano-sheet of PMOSFET than in the nano-sheet of NMOSFET. However, embodiments are not particularly limited thereto, and may be changed based on detailed conditions of semiconductor devices.

The superlattice layer EPL in the second channel pattern CH2 may have a thickness different from that of the superlattice layer EPL in the first channel pattern CH1. For example, the superlattice layer EPL in the second semiconductor pattern SP2 may have a fourth thickness TK4. The superlattice layer EPL in the first channel pattern CH1 may have a third thickness TK3 (see FIG. 6). For example, the fourth thickness TK4 may be less than the third thickness TK3.

In a three-dimensional field effect transistor according to embodiments, a nano-sheet may have a superlattice structure. Thus, a channel carrier mobility may be increased and a channel resistance may be decreased, with the result that a device may improve in electrical properties. As the nano-sheet has the superlattice structure, a short channel effect may be prevented. In a semiconductor device according to embodiments, the number and thickness of superlattice layers may be changed depending on tier of the nano-sheet, and thus optimum electrical properties and process efficiency may be achieved.

While embodiments have been described with reference to the figures, it will be understood by those of ordinary skill in the art that various changes in form and details may be made therein without departing from the spirit and scope as defined by the following claims and their equivalents.

What is claimed is:

1. A semiconductor device, comprising:
a substrate;
a first active pattern on the substrate;
a first channel pattern on the first active pattern, the first channel pattern comprising a first semiconductor pattern and a second semiconductor pattern on the first semiconductor pattern;
a first source/drain pattern connected to the first channel pattern; and
a gate electrode on the first channel pattern,
wherein each of the first semiconductor pattern and the second semiconductor pattern comprises:
a plurality of semiconductor layers; and
at least one superlattice layer between adjacent semiconductor layers among the plurality of semiconductor layers,
wherein the at least one superlattice layer included in the first semiconductor pattern has a first length,
wherein the at least one superlattice layer included in the second semiconductor pattern has a second length, and
wherein the first length is greater than the second length.

2. The semiconductor device of claim 1, wherein a number of the at least one superlattice layer included in the second semiconductor pattern is greater than a number of the at least one superlattice layer included in the first semiconductor pattern.

3. The semiconductor device of claim 1, wherein a thickness of the at least one superlattice layer included in the second semiconductor pattern is different from a thickness of the at least one superlattice layer included in the first semiconductor pattern.

4. The semiconductor device of claim 1, wherein a thickness of the at least one superlattice layer is less than a thickness of each of the plurality of semiconductor layers.

5. The semiconductor device of claim 1, wherein each of the plurality of semiconductor layers includes silicon, and
wherein the at least one superlattice layer comprises at least one of germanium (Ge), gallium arsenide (GaAs), indium arsenide (InAs), indium antimonide (InSb), and indium phosphide (InP).

6. The semiconductor device of claim 1, further comprising:
a second active pattern on the substrate;
a second channel pattern on the second active pattern, the second channel pattern comprising a third semiconductor pattern and a fourth semiconductor pattern on the third semiconductor pattern; and
a second source/drain pattern connected to the second channel pattern,
wherein a conductivity type of the second source/drain pattern is different from a conductivity type of the first source/drain pattern,
wherein each of the third semiconductor pattern and the fourth semiconductor pattern comprises:
a plurality of semiconductor layers; and
at least one superlattice layer between the plurality of semiconductor layers,
wherein a number of the at least one superlattice layer included in the second semiconductor pattern is less than a number of the at least one superlattice layer included in the fourth semiconductor pattern.

7. The semiconductor device of claim 1, wherein the gate electrode comprises an inner electrode between the first semiconductor pattern and the second semiconductor pattern.

8. The semiconductor device of claim 1, wherein the first source/drain pattern comprises a pair of first source/drain patterns, and
wherein the at least one superlattice layer connects the pair of first source/drain patterns to each other.

9. The semiconductor device of claim 1, wherein the first channel pattern further comprises a third semiconductor pattern below the first semiconductor pattern.

10. The semiconductor device of claim 9, wherein the third semiconductor pattern is located at a lowermost tier in the first channel pattern.

11. A semiconductor device, comprising:
a substrate comprising an active pattern;
a channel pattern on the active pattern, the channel pattern comprising a plurality of nano-sheets vertically stacked and spaced apart from each other;
a source/drain pattern connected to the channel pattern; and
a gate electrode on the channel pattern,
wherein each of the plurality of nano-sheets comprises semiconductor layers and superlattice layers that are alternately stacked, and
wherein a number of the superlattice layers in a first tier of the plurality of nano-sheets is greater than a number of the superlattice layers in a second tier of the plurality of nano-sheets, the first tier being above the second tier.

12. The semiconductor device of claim 11, wherein the gate electrode comprises a plurality of inner electrodes between the plurality of nano-sheets.

13. The semiconductor device of claim 11, wherein a lowermost tier of the plurality of nano-sheets does not comprise a superlattice layer.

14. The semiconductor device of claim 11, wherein each of the semiconductor layers includes silicon, and
wherein each of the superlattice layers includes at least one of germanium (Ge), gallium arsenide (GaAs), indium arsenide (InAs), indium antimonide (InSb), and indium phosphide (InP).

15. The semiconductor device of claim 11, wherein a length of each of the superlattice layers in the first tier is different from a length of each of the superlattice layers in the second tier.

16. A semiconductor device, comprising:
a substrate comprising an active pattern;
a device isolation layer filling a trench;
a channel pattern and a source/drain pattern on the active pattern, the channel pattern comprising a plurality of nano-sheets that are vertically stacked and spaced apart from each other;
a gate electrode on the channel pattern, the gate electrode comprising a plurality of inner electrodes between the plurality of nano-sheets;
a gate dielectric layer adjacent to each of the plurality of inner electrodes included in the gate electrode;
a gate spacer on a sidewall of the gate electrode;
a gate capping pattern on a top surface of the gate electrode;
an interlayer dielectric layer on the gate capping pattern;
an active contact penetrating the interlayer dielectric layer and electrically connected to the source/drain pattern;
a metal-semiconductor compound layer between the active contact and the source/drain pattern;
a gate contact penetrating the interlayer dielectric layer and the gate capping pattern and electrically connected to the gate electrode; and
a first metal layer on the interlayer dielectric layer,
wherein the first metal layer comprises a plurality of first wiring lines electrically connected to the active contact and the gate contact,
wherein each of the plurality of nano-sheets comprises at least one superlattice layer, and
wherein a number of the at least one superlattice layer in each of the plurality of nano-sheets increases in a direction from a lowermost nano-sheet among the plurality of nano-sheets toward an uppermost nano-sheet among the plurality of nano-sheets.

17. The semiconductor device of claim 16, wherein each of the plurality of nano-sheets comprises a plurality of semiconductor layers and a superlattice layer between the plurality of semiconductor layers.

18. The semiconductor device of claim 17, wherein a thickness of the at least one superlattice layer is less than a thickness of each of the plurality of semiconductor layers.

19. The semiconductor device of claim 17, wherein each of the plurality of semiconductor layers includes silicon, and
wherein the at least one superlattice layer includes at least one of germanium (Ge), gallium arsenide (GaAs), indium arsenide (InAs), indium antimonide (InSb), and indium phosphide (InP).

20. The semiconductor device of claim 17, wherein a thickness of the at least one superlattice layer in each of the plurality of nano-sheets decreases in the direction from the lowermost nano-sheet among the plurality of nano-sheets toward the uppermost nano-sheet among the plurality of nano-sheets.
